(19) United States
(12) Patent Application Publication
(10) Pub. No.: US 2026/0305075 A1
(43) Pub. Date: Oct. 1, 2026

(54) DISPLAY PANEL AND METHOD FOR MANUFACTURING SAME, AND DISPLAY DEVICE

(71) Applicant: BOE Technology Group Co., Ltd., Beijing (CN)

(72) Inventors: Wei YANG, Beijing (CN); Qingyu HUANG, Beijing (CN); Shaopeng YANG, Beijing (CN); Shuilang DONG, Beijing (CN)

(21) Appl. No.: 18/992,179

(22) PCT Filed: Aug. 16, 2024
(86) PCT No.: PCT/CN2024/112718

§ 371 Date: Jan. 7, 2025

(30) Foreign Application Priority Data
Sep. 25, 2023 (CN) 202311246978.1

(51) Int. Cl. H10K 59/122; H10K 59/12; H10K 59/131

(52) U.S. Cl. CPC H10K 59/122; H10K 59/1201; H10K 59/131

(57) ABSTRACT

Provided is a display panel. The display panel includes a base substrate, wherein the base substrate includes a display region and a periphery region surrounding the display region; a plurality of light-emitting units, wherein the plurality of light-emitting units are disposed on a side of the base substrate and disposed in the display region, and each of the plurality of light-emitting units includes a first electrode layer, a pixel definition layer, an organic functional film layer, and a second electrode layer that are sequentially stacked in a direction away from the base substrate; a plurality of drive circuits corresponding to the plurality of light-emitting units, wherein the plurality of drive circuits are disposed between the base substrate and the plurality of light-emitting units, and each of the plurality of drive circuits is connected to a corresponding light-emitting unit to provide a drive signal to the corresponding light-emitting unit.

This application is a U.S. national stage of international application No. PCT/CN2024/112718, filed on Aug. 16, 2024, which claims priority to Chinese Patent Application No. 202311246978.1, filed on Sep. 25, 2023 and entitled “DISPLAY PANEL, PREPARATION METHOD THEREOF AND DISPLAY DEVICE,” the disclosures of which are herein incorporated by references in their entireties.

### TECHNICAL FIELD

The present disclosure relates to the field of display technologies, and in particular, relates to a display panel and a method for manufacturing the same, and a display device.

### BACKGROUND

An organic light-emitting diode (OLED) display panel is widely used due to advantages, such as self-luminescence, low drive voltage, and fast response.

### SUMMARY

Embodiments of the present disclosure provide a display panel and a method for manufacturing the same, and a display device. The technical solutions are as follows.

In some embodiments of the present disclosure, a display panel is provided. The display panel includes:

a base substrate, wherein the base substrate includes a display region and a periphery region surrounding the display region;

a plurality of light-emitting units, wherein the plurality of light-emitting units are disposed on a side of the base substrate and disposed in the display region, and each of the plurality of light-emitting units includes a first electrode layer, a pixel definition layer, an organic functional film layer, and a second electrode layer that are sequentially stacked in a direction away from the base substrate, wherein the first electrode layer includes a target electrode layer and a protection electrode layer that are stacked in the direction away from the base substrate, an orthographic projection of the protection electrode layer on the base substrate covering an orthographic projection of the target electrode layer on the base substrate; and the organic functional film layer at least includes a charge generation layer; and

a plurality of drive circuits corresponding to the plurality of light-emitting units, wherein the plurality of drive circuits are disposed between the base substrate and the plurality of light-emitting units, and each of the plurality of drive circuits is connected to a corresponding light-emitting unit to provide a drive signal to the corresponding light-emitting unit;

wherein the display panel further includes a partition structure between light-emitting regions of any adjacent two of the plurality of light-emitting units; the protection electrode layer at least includes a first protection pattern and a second protection pattern that are spaced apart by a first spacer; the pixel definition layer at least includes a first definition pattern and a second definition pattern that are spaced apart by a second spacer, wherein the first spacer is greater than the second spacer, and the partition structure includes the first spacer and the second spacer; a portion of the charge generation layer in the partition structure is incontiguous to a portion of the charge generation layer in a light-emitting region of each of the plurality of light-emitting units; and a portion of the second electrode layer in the partition structure is contiguous to a portion of the second electrode layer in the light-emitting region of each of the plurality of light-emitting units.

In some embodiments, the display panel further includes: an organic insulative layer and an inorganic protection layer that are disposed between the plurality of light-emitting units and the plurality of drive circuits and stacked in the direction away from the base substrate, wherein

the target electrode layer is connected to each of the plurality of drive circuits through a first via in the inorganic protection layer and a second via in the organic insulative layer.

In some embodiments, the display panel further includes: an organic insulative layer between the plurality of light-emitting units and the plurality of drive circuits; and the first electrode layer further includes a connection electrode layer on a side, close to the base substrate, of the target electrode layer, wherein the connection electrode layer is connected to each of the plurality of drive circuits through a second via in the organic insulative layer,

the connection electrode layer and the protection electrode layer are formed by a same patterning process, and the connection electrode layer at least includes a first connection pattern and a second connection pattern that are spaced apart by a third spacer, wherein the partition structure further includes the third spacer.

In some embodiments, the connection electrode layer and the protection electrode layer are made of a same material, and the third spacer is equal to the first spacer; or

the connection electrode layer and the protection electrode layer are made of different materials, and the third spacer is not equal to the first spacer.

In some embodiments, in a case that the connection electrode layer and the protection electrode layer are made of a same material, the connection electrode layer and the protection electrode layer are made of indium tin oxide (ITO).

In some embodiments, in a case that the connection electrode layer and the protection electrode layer are made of different materials, the connection electrode layer is made of molybdenum (Mo), and the protection electrode layer 10212 is made of ITO.

In some embodiments of the present disclosure, a method for manufacturing a display panel is provided. The method includes:

acquiring a base substrate, wherein the base substrate includes a display region and a periphery region surrounding the display region;

forming a plurality of drive circuits on a side of the base substrate; and

forming a plurality of light-emitting units on a side, away from the base substrate, of the plurality of drive circuits, wherein the plurality of light-emitting units are disposed in the display region and correspond to the plurality of drive circuits, and each of the plurality of drive circuits is connected to a corresponding light-emitting unit to provide a drive signal to the corresponding light-emitting unit;

wherein forming the plurality of light-emitting units includes:

forming a connection electrode thin film on the side, away from the base substrate, of the plurality of drive circuits;

forming a target electrode thin film on a side, away from the base substrate, of the connection electrode thin film, and acquiring a target electrode layer by patterning the target electrode thin film;

forming a protection electrode thin film on a side, away from the base substrate, of the target electrode thin film;

acquiring a protection electrode layer by processing the protection electrode thin film using a first etching process, and acquiring a connection electrode layer by processing the connection electrode thin film using a second etching process, wherein the first etching process and the second etching process are a same patterning process, the connection electrode layer at least includes a first connection pattern and a second connection pattern that are spaced apart by a first spacer, and the protection electrode layer at least includes a first protection pattern and a second protection pattern that are spaced apart by a second spacer, wherein the first spacer is greater than the second spacer, and the first spacer and the second spacer form a partition structure;

forming a pixel electrode layer on a side, away from the base substrate, of the protection electrode layer, wherein a portion of the pixel electrode layer in the partition structure is incontiguous to a portion of the pixel electrode layer in a light-emitting region of each of the plurality of light-emitting units;

forming an organic functional film layer on a side, away from the base substrate, of the pixel electrode layer, wherein the organic functional film layer at least includes a charge generation layer, a portion of the charge generation layer in the partition structure being incontiguous to a portion of the charge generation layer in the light-emitting region of each of the plurality of light-emitting units; and

forming a second electrode layer on a side, away from the base substrate, of the organic functional film layer, wherein a portion of the second electrode layer in the partition structure is contiguous to a portion of the second electrode layer in the light-emitting region of each of the plurality of light-emitting units.

In some embodiments of the present disclosure, a display device is provided. The display device includes: a power supply assembly, and the display panel as defined in the above embodiments, wherein the power supply assembly is configured to supply power to the display panel.

### BRIEF DESCRIPTION OF DRAWINGS

For clearer description of the technical solutions according to the embodiments of the present disclosure, the following briefly introduces the accompanying drawings required for describing the embodiments. Apparently, the accompanying drawings in the following description show merely some embodiments of the present disclosure, and persons of ordinary skill in the art may still derive other drawings from these accompanying drawings without creative efforts.

FIG. 1 is a schematic diagram of a display panel according to some embodiments of the present disclosure;

FIG. 2 is a schematic diagram of a currently common method for manufacturing a display panel according to some embodiments of the present disclosure;

FIG. 3 is a schematic structural diagram of a display panel according to some embodiments of the present disclosures;

FIG. 4 is a top view of a base substrate according to some embodiments of the present disclosure;

FIG. 5 is a schematic structural diagram of a display panel according to some embodiments of the present disclosures;

FIG. 6 is a schematic structural diagram of a display panel according to some embodiments of the present disclosures;

FIG. 7 is a schematic structural diagram of a display panel according to some embodiments of the present disclosures;

FIG. 8 is a schematic structural diagram of a display panel according to some embodiments of the present disclosures;

FIG. 9 is a schematic structural diagram of a display panel according to some embodiments of the present disclosures;

FIG. 10 isa schematic structural diagram of a display panel according to some embodiments of the present disclosures;

FIG. 11 is a schematic structural diagram of a display panel according to some embodiments of the present disclosures;

FIG. 12 is a schematic structural diagram of a display panel according to some embodiments of the present disclosures;

FIG. 13 is a schematic structural diagram of a display panel according to some embodiments of the present disclosures;

FIG. 14 is a flowchart of a method for manufacturing a display panel according to some embodiments of the present disclosure;

FIG. 15 is a structural flowchart of some processes in a method for manufacturing a display panel according to some embodiments of the present disclosure;

FIG. 16 is a flowchart of a method for manufacturing a display panel according to some embodiments of the present disclosure;

FIG. 17 is a structural flowchart of some processes in a method for manufacturing a display panel according to some embodiments of the present disclosure;

FIG. 18 is a flowchart of a method for manufacturing a display panel according to some embodiments of the present disclosure;

FIG. 19 is a structural flowchart of some processes in a method for manufacturing a display panel according to some embodiments of the present disclosure;

FIG. 20 is a flowchart of a method for manufacturing a display panel according to some embodiments of the present disclosure;

FIG. 21 is a structural flowchart of some processes in a method for manufacturing a display panel according to some embodiments of the present disclosure;

FIG. 22 is a flowchart of a method for manufacturing a display panel according to some embodiments of the present disclosure;

FIG. 23 is a structural flowchart of some processes in a method for manufacturing a display panel according to some embodiments of the present disclosure;

FIG. 24 is a flowchart of a method for manufacturing a display panel according to some embodiments of the present disclosure;

FIG. 25 is a structural flowchart of some processes in a method for manufacturing a display panel according to some embodiments of the present disclosure;

FIG. 26 is a flowchart of a method for manufacturing a display panel according to some embodiments of the present disclosure;

FIG. 27 is a structural flowchart of some processes in a method for manufacturing a display panel according to some embodiments of the present disclosure;

FIG. 28 is a flowchart of a method for manufacturing a display panel according to some embodiments of the present disclosure;

FIG. 29 is a structural flowchart of some processes in a method for manufacturing a display panel according to some embodiments of the present disclosure; and

FIG. 30 is a schematic structural diagram of a display device according to some embodiments of the present disclosure.

### DETAILED DESCRIPTION

For clearer descriptions of the objects, technical solutions, and advantages of the embodiments of present disclosure, the embodiments of the present disclosure are described in detail hereinafter in combination with the accompanying drawings.

In some practices, the OLED display panel includes a plurality of OLED devices. Each OLED device generally includes an anode, an organic functional film layer, and a cathode. The organic functional film layer emits light under driving of the anode and the cathode. In general, the plurality of OLED devices in the OLED display panel are in tandem through a connection layer in the organic functional film layer to improve luminance of the OLED display panel and reduce power consumption of the OLED display panel, such that a high-efficiency OLED device is acquired.

However, the carrier mobility of the charge generation layer (CGL) in the connection layer is high, such that the transverse leakage current may be generated, and thus the display effect of the display panel is poor.

In recent years, with increment of the pixels per inch (PPI) of the display product, such as virtual reality (VR) and augmented reality (AR), an area of a pixel unit is smaller, which gives higher requirements for layout design and process capability.

In some practices, the anode (AND) of the currently common OLED device is made of a three-stack structure consisting of ITO, argentum (Ag), and ITO (denoted as ITO/Ag/ITO). The anode pattern is generally formed by etching using a wet process. As the etching solution of the anode pattern is viscous, such that distances between the anode patterns of different pixel units are great to avoid short-circuiting of the anode patterns of different pixel units due to material residues. In addition, due to the large etched critical dimension (CD) bias of ITO/Ag/ITO using the wet etching process, the layout design of the anode is difficult, and the size of the void region of the pixel definition layer is reduced. Thus, the aperture ratio of the OLED display panel is reduced, the luminous efficiency is affected, and the power consumption of the OLED display panel is further increased.

In general, the tandem OLED technology is used to improve luminance of the OLED display panel and reduce power consumption of the OLED display panel. However, the CGL (including the n-type CGL and the p-type CGL) in the tandem OLED technology requires a high carrier mobility, such that the transverse leakage current may be generated, and thus the luminous efficiency of the display panel is affected.

Compared with the wet etching, the dry etching reduces the distance between the anode patterns and improve the PPI of the OLED display panel. Thus, the anode thin film is etched using the dry etching process. However, in the case that the anode thin film is etched using the dry etching process, the following problems are generated.

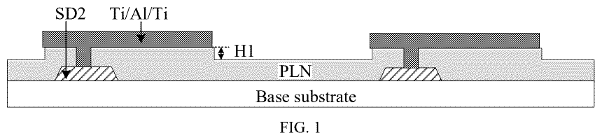

1. The ITO/Ag/ITO is not prone to being etched using the dry etching process, and thus the ITO/Ag/ITO is replaced by other metals, such as ITO/titanium (Ti)/aluminum (Al)/Ti, and the like. However, in the process of etching the ITO/Ti/Al/Ti, the organic insulative layer (PLN) under the ITO/Ti/Al/Ti is prone to being etched and damaged, with a damage thickness HI being greater than 100 nm, referring to FIG. 1. In this case, the cathode layer above the charge generation layer is also spaced apart in partitioning the charge generation layer to cause abnormal display. Thus, an inorganic protection layer (PVX) is deposited between the organic insulative layer and the/Ti/Al/Ti. In addition, a patterning process is added to form the via in the inorganic protection layer to connect Ti/Al/Ti and the drive circuits under Ti/Al/Ti.

2. Al is prone to corrosion, and thus a protection layer is required to protect the sidewall. In the case that the ITO/Ti/Al/Ti in the anode layer is processed by a same patterning process, the sidewall of Al is not protected by ITO, and thus is prone to corrosion to cause abnormal display. Thus, ITO and Ti/Al/Ti processed by two patterning processes. That is, a pattern of Ti/Al/Ti is first formed by a first patterning process, and a pattern of ITO is then formed by a second patterning process.

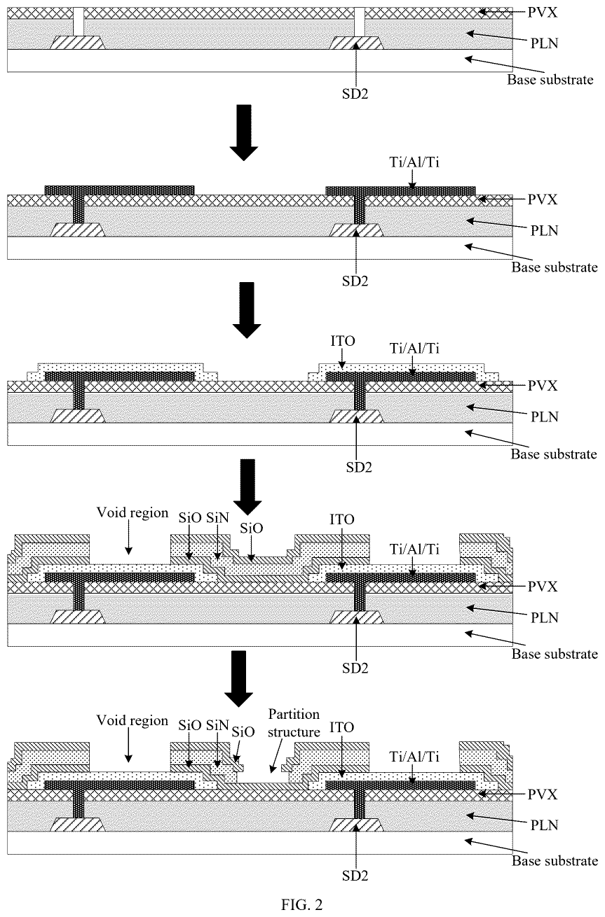

Based on the above description, referring to FIG. 2, the currently common methos needs five patterning processes shown as follows.

1. A via of the inorganic protection layer (PVX) is formed. An inorganic protection thin film is formed on a side, away from the base substrate, of the organic insulative layer (PLN), and the inorganic protection layer is acquired by processing the inorganic protection thin film using a patterning process. The via is defined in the inorganic protection layer, and is configured to connect subsequently formed Ti/Al/Ti and a signal transmission portion (in a second source-drain electrode layer (SD2)) of the drive circuits. The inorganic protection layer is configured to avoid etching damage on the organic insulative layer in subsequent process of dry-etching Ti/Al/Ti.

2. A Ti/Al/Ti (as an anode pattern) pattern is formed. An anode thin film is formed on a side, away from the base substrate, of the inorganic protection layer, and the anode pattern is acquired by processing the anode thin film using a patterning process.

3. An ITO pattern (as a protection pattern of the anode pattern) pattern is formed. A protection thin film is formed on a side, away from the base substrate, of the anode pattern, and the protection pattern is acquired by processing the protection thin film using a patterning process. The protection pattern covers the sidewall of the anode pattern to avoid corrosion of the anode pattern and abnormal display.

4. A void region of the pixel definition layer is formed. A pixel definition thin film is formed on a side, away from the base substrate, of the protection pattern, and an initial pixel definition layer is acquired by processing the pixel definition thin film using a patterning process. The pixel definition thin film include three thin films, that is, silicon oxide (SiO)/silicon nitride (SiN)/SiO.

5. A partition structure is formed. The pixel definition layer is acquired by processing the initial pixel definition layer using a patterning process.

It can be seen from the above common process that the common process has the following problems.

1. Five patterning process are required, and thus the manufacturing cost is high.

2. An etching rate of SiO is less than an etching rate of SiN by adjusting the etching condition in etching the SiO, such that an undercut width w is formed. However, the undercut width w is difficult to control.

3. SiO in the upper layer of the pixel definition layer functions as partitioning. As SiO is an inorganic material, and thus is prone to breaking upon being squeezed by the organic functional film layer, such that the partitioning effect is affected.

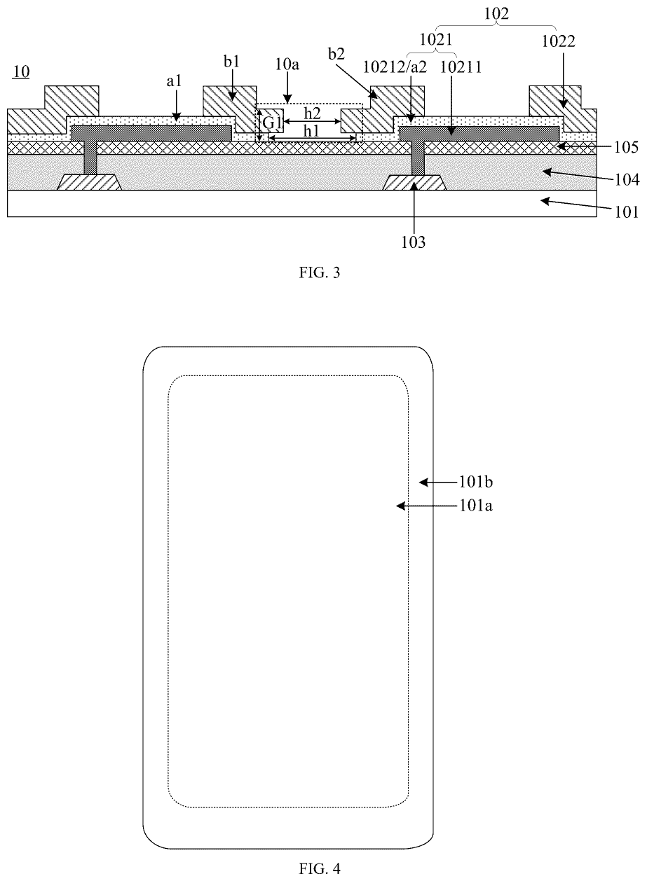

FIG. 3 is a schematic structural diagram of a display panel according to some embodiments of the present disclosures. It can be seen referring to FIG. 3 that the display panel 10 includes a base substrate 101, a plurality of light-emitting units 102, and a plurality of drive circuits 103. FIG. 4 is a top view of a base substrate according to some embodiments of the present disclosure. Referring to FIG. 4, the base substrate 101 includes a display region 101a and a periphery region 101b surrounding the display region 101a.

In conjunction with FIG. 3 and FIG. 4, the plurality of light-emitting units 102 are disposed on a side of the base substrate 101 and disposed in the display region 101a. Each of the plurality of light-emitting units 102 includes a first electrode layer 1021, a pixel definition layer 1022, an organic functional film layer (not shown in the drawing), and a second electrode layer (not shown in the drawing) that are sequentially stacked in a direction away from the base substrate 101.

The first electrode layer 1021 includes a target electrode layer 10211 and a protection electrode layer 10212 that are stacked in the direction away from the base substrate 101. An orthographic projection of the protection electrode layer 10212 on the base substrate 101 covers an orthographic projection of the target electrode layer 10211 on the base substrate 101 to avoid affecting the target electrode layer 10211 in the subsequent process and ensuring the yield of the target electrode layer 10211. The organic functional film layer at least includes a charge generation layer.

The plurality of drive circuits 103 are disposed between the base substrate 101 and the plurality of light-emitting units 102, and each of the plurality of drive circuits 103 is connected to a corresponding light-emitting unit 102 to provide a drive signal to the corresponding light-emitting unit 102.

Referring to FIG. 3, the display panel 10 further includes a partition structure 10a between light-emitting regions of any adjacent two of the plurality of light-emitting units 102. The protection electrode layer 10212 at least includes a first protection pattern a1 and a second protection pattern a2 that are spaced apart by a first spacer h1, and the pixel definition layer 1022 at least includes a first definition pattern b1 and a second definition pattern b2 that are spaced apart by a second spacer h2. The first spacer h1 is greater than the second spacer h2, and the partition structure 10a includes the first spacer h1 and the second spacer h2.

In the embodiments of the present disclosure, as the second spacer h2 between the first definition pattern b1 and the second definition pattern b2 in the pixel definition layer 1022 is less than the first spacer h1 between the first protection pattern a1 and the second protection pattern a2 in the protection electrode layer 10212, the definition pattern in the pixel definition layer 1022 covers the protection pattern in the protection electrode layer 10212, and the definition pattern includes a portion protruding from the protection pattern. That is, the protection electrode layer 10212 forms an undercut relative to the pixel definition layer 1022.

Furthermore, the pixel definition layer 1022 is farther away from the base substrate 101 than the protection electrode layer 10212, and thus some film layers subsequently formed on a side, away from the base substrate 101, of the pixel definition layer 1022 cannot be formed sequentially along the protection pattern and the pixel pattern and are incontiguous at the partition structure 10a. Thus, the transverse leakage current due to the high carrier mobility of the film layer is avoided, and the luminous efficiency is ensured.

In the embodiments of the present disclosure, in general, various film layers on the side, away from the base substrate 101, of the pixel definition layer 1022 in the display panel 10 are increasingly not spaced apart by the partition structure 10a with increment of distances between the various film layers and the pixel definition layer 1022. Thus, the thicknesses of the protection electrode layer 10212 and the pixel electrode layer are adjusted to adjust the partitioning effect of the partition structure 10a on the various film layers on the side, away from the base substrate 101, of the pixel definition layer 1022 in the display panel 10.

In some embodiments, as the second electrode layer is farther away from the pixel definition layer 1022 than the charge generation layer, the charge generation layer is prone to being spaced apart by the partition structure 10a than the second electrode layer. Thus, by adjusting the thicknesses of the protection electrode layer 10212 and the pixel definition layer 1022, the charge generation layer is spaced apart by the partition structure 10a, and the second electrode layer is not spaced apart by the partition structure 10a.

Illustratively, a portion of the charge generation layer in the partition structure 10a is incontiguous to a portion of the charge generation layer in a light-emitting region of each of the plurality of light-emitting units 102, and a portion of the second electrode layer in the partition structure 10a is contiguous to a portion of the second electrode layer in the light-emitting region of each of the plurality of light-emitting units 102.

As the charge generation layer is spaced apart by the partition structure 10a, the transverse leakage current is not generated between the adjacent light-emitting units 102 even if the carrier mobility of the charge generation layer is high. In addition, the second electrode layer acts as the cathode of the light-emitting unit 102 and is not spaced apart by the partition structure 10a, and thus the light-emitting units 102 display normally.

In summary, the embodiments of the present disclosure provide a display panel. The display panel includes a base substrate, and a plurality of drive circuits and a plurality of light-emitting units on the base substrate. In addition, the display panel further includes a partition structure. The charge generation layer in the organic functional film layer is spaced apart by the partition structure, and the second electrode layer is not spaced apart by the partition structure, such that the display function of the display panel is ensured, the transverse leakage current is avoided, and the display effect is ensured.

It can be further seen referring to FIG. 3 that the display panel further includes an organic insulative layer 104 and an inorganic protection layer 105 that are disposed between the plurality of light-emitting units 102 and the plurality of drive circuits 103 and stacked in the direction away from the base substrate 101. The target electrode layer 10211 is connected to each of the plurality of drive circuits 103 through a first via in the inorganic protection layer 105 and a second via in the organic insulative layer 104.

In some embodiments, the process for manufacturing the target electrode layer 10211 includes forming a target electrode thin film and then acquiring the target electrode layer 10211 by processing the target electrode thin film using a patterning process. The patterning process includes photoresist coating, exposing, developing, etching, and photoresist removing. The etching process is the dry etching process.

In general, the material of the organic insulative layer 104 is prone to being affected by the dry etching process, and the material of the inorganic protection layer 105 is not prone to being affected by the dry etching process. Thus, the inorganic protection layer 105 is disposed on the side, away from the base substrate 101, of the organic insulative layer 104 to avoid over-etching the organic insulative layer 104 in forming the target electrode layer 10211 and to further avoid partition of the second electrode layer due to a great height of the partition structure 10a. In FIG. 3, the height of the partition structure 10a is a total thickness G1 of the protection electrode layer 10212 and the pixel definition layer 1022.

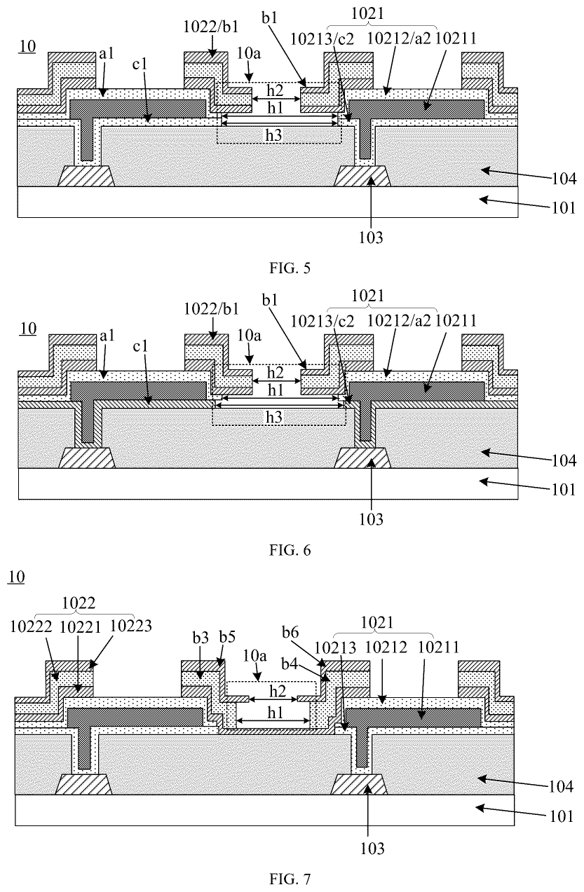

FIG. 5 is a schematic structural diagram of a display panel according to some embodiments of the present disclosures. Referring to FIG. 5, the display panel further includes an organic insulative layer 104 between the plurality of light-emitting units 102 and the plurality of drive circuits 103. The first electrode layer 1021 further includes a connection electrode layer 10213 on a side, close to the base substrate 101, of the target electrode layer 10211. The connection electrode layer 10213 is connected to each of the plurality of drive circuits 103 through a second via in the organic insulative layer 104.

The connection electrode layer 10213 and the protection electrode layer 10212 are formed by a same patterning process, and the connection electrode layer 10213 at least includes a first connection pattern c1 and a second connection pattern c2 that are spaced apart by a third spacer h3. The partition structure 10a further includes the third spacer h3. The same patterning process in the embodiments of the present hereinafter refers to a whole process including photoresist coating, exposing, developing, etching, and photoresist removing. For the etching process in the same patterning process, different etching conditions may be used for different film layers.

In general, the material of the organic insulative layer 104 is not affected by the wet etching process, and thus it is unnecessary to dispose the inorganic protection layer 105 on the side, away from the base substrate 101, of the organic insulative layer 104 in the case that the etching process in the patterning process used for the connection electrode layer 10213 and the protection electrode layer 10212 is the wet etching process.

In some embodiments, the connection electrode layer 10213 and the protection electrode layer 10212 are made of the same material. In this case, referring to FIG. 5, the third spacer h3 is equal to the first spacer h1. For example, the connection electrode layer 10213 and the protection electrode layer 10212 are made of ITO.

Alternatively, the connection electrode layer 10213 and the protection electrode layer 10212 are made of different materials. In this case, referring to FIG. 6, the third spacer h3 is not equal to the first spacer h1. For example, the connection electrode layer 10213 is made of Mo, and the protection electrode layer 10212 is made of ITO. As the etching CD bias of the wet etching process on Mo is greater than the etching CD bias of the wet etching process on ITO, the connection electrode layer 10213 has the undercut relative to the protection electrode layer 10212. That is, the third spacer h3 is greater than the first spacer h1.

In the embodiments of the present disclosure, the drive circuit 103 includes a plurality of thin-film transistors and at least one storage capacitor. In some embodiments, the drive circuit 103 includes seven thin-film transistors and one storage capacitor. That is, the drive circuit 103 is a 7T1C circuit. Alternatively, the drive circuit 103 includes another number of thin-film transistors and another number of storage capacitors. The embodiments of the present disclosure do not limit the number of thin-film transistors and the number of storage capacitors in the drive circuit 103.

Each thin-film transistor includes a gate electrode, a source electrode, and a drain electrode. The plurality of thin-film transistors in the drive circuit 103 are connected to each other to drive the light-emitting units 102 to emit light.

In some embodiments, the drain electrode of one of the plurality of thin-film transistors in the drive circuit in the drive circuit is connected to the light-emitting unit 102. The drive circuits 103 in FIG. 3, FIG. 5, and FIG. 6 represent the signal transmission portion in the drive circuit for transmitting signals. The signal transmission portion is disposed on a second source-drain electrode layer of the display panel.

In summary, the embodiments of the present disclosure provide a display panel. The display panel includes a base substrate, and a plurality of drive circuits and a plurality of light-emitting units on the base substrate. In addition, the display panel further includes a partition structure. The charge generation layer in the organic functional film layer is spaced apart by the partition structure, and the second electrode layer is not spaced apart by the partition structure, such that the display function of the display panel is ensured, the transverse leakage current is avoided, and the display effect is ensured.

FIG. 7 is a schematic structural diagram of a display panel according to some embodiments of the present disclosures. Referring to FIG. 7, the display panel 10 includes the base substrate 101, a plurality of light-emitting units 102, and a plurality of drive circuits 103. Referring to FIG. 2, the base substrate 101 includes a display region 101a and a periphery region 101b surrounding the display region 101a.

In conjunction with FIG. 1 and FIG. 2, the plurality of light-emitting units 102 are disposed on a side of the base substrate 101 and disposed in the display region 101a. Each of the plurality of light-emitting units 102 includes a first electrode layer 1021, a pixel definition layer 1022, an organic functional film layer (not shown in the drawing), and a second electrode layer (not shown in the drawing) that are sequentially stacked in a direction away from the base substrate 101. The organic functional film layer at least includes a charge generation layer. The second electrode layer is a cathode of the light-emitting unit 102.

The first electrode layer 1021 includes a connection electrode layer 10213, a target electrode layer 10211, and a protection electrode layer 10212 that are stacked in the direction away from the base substrate 101. The connection electrode layer 10213 and the protection electrode layer 10212 are made of the same material, for example, ITO. In addition, the connection electrode layer 10213 and the protection electrode layer 10212 are formed by a same patterning process, such that an orthographic projection of the protection electrode layer 10212 on the base substrate 101 is overlapped with an orthographic projection of the connection electrode layer 10213 on the base substrate 101.

In addition, the orthographic projection of the protection electrode layer 10212 on the base substrate 101 and the orthographic projection of the connection electrode layer 10213 on the base substrate 101 both cover an orthographic projection of the target electrode layer 10211 on the base substrate 101. Thus, in the subsequent process, the effect on the target electrode layer 10211 is avoided, and the yield of the target electrode layer 10211 is ensured.

The plurality of drive circuits 103 are disposed between the base substrate 101 and the plurality of light-emitting units 102, and each of the plurality of drive circuits 103 is connected to a corresponding light-emitting unit 102 to provide a drive signal to the corresponding light-emitting unit 102.

Referring to FIG. 7, the display panel 10 further includes a partition structure 10a between light-emitting regions of any adjacent two of the plurality of light-emitting units 102. The pixel definition layer 1022 includes a first definition layer 10221, a second definition layer 10222, and a third definition layer 10223 that are stacked in the direction away from the base substrate 101. The first definition layer 10221 is contiguous, the second definition layer 10222 at least includes a third definition pattern b3 and a fourth definition pattern b4 that are spaced apart by a first spacer h1, and the third definition layer 10223 at least includes a fifth definition pattern b5 and a sixth definition pattern b6 that are spaced apart by a second spacer h2. The first spacer h1 is greater than the second spacer h2, and the partition structure 10a includes the first spacer h1 and the second spacer h2.

In the embodiments of the present disclosure, as the second spacer h2 between the fifth definition pattern b5 and the sixth definition pattern b6 in the third definition layer 10223 is less than the first spacer h1 between the third definition pattern b3 and the fourth definition pattern b4 in the second definition layer 10222, the definition patten in the third definition layer 10223 covers the definition patten in the second definition layer 10222, and the definition patten in the third definition layer 10223 includes a portion protruding from the definition patten in the second definition layer 10222. That is, the second definition layer 10222 forms an undercut relative to the third definition layer 10223.

Furthermore, the third definition layer 10223 is farther away from the base substrate 101 than the second definition layer 10222, and thus some film layers subsequently formed on a side, away from the base substrate 101, of the pixel definition layer 1022 cannot be formed sequentially along the definition patten in the third definition layer 10223 and the definition patten in the second definition layer 10222 and are incontiguous at the partition structure 10a. Thus, the transverse leakage current due to the high carrier mobility of the film layer is avoided, and the luminous efficiency is ensured.

In the embodiments of the present disclosure, in general, various film layers on the side, away from the base substrate 101, of the pixel definition layer 1022 in the display panel 10 are increasingly not spaced apart by the partition structure 10a with increment of distances between the various film layers and the pixel definition layer 1022. Thus, the thicknesses of the second definition layer 10222 and the third definition layer 10223 are adjusted to adjust the partitioning effect of the partition structure 10a on the various film layers on the side, away from the base substrate 101, of the pixel definition layer 1022 in the display panel 10.

In some embodiments, as the second electrode layer is farther away from the pixel definition layer 1022 than the charge generation layer, the charge generation layer is prone to being spaced apart by the partition structure 10a than the second electrode layer. Thus, by adjusting the thicknesses of the second definition layer 10222 and the third definition layer 10223, the charge generation layer is spaced apart by the partition structure 10a, and the second electrode layer is not spaced apart by the partition structure 10a.

Illustratively, a portion of the charge generation layer in the partition structure 10a is incontiguous to a portion of the charge generation layer in a light-emitting region of each of the plurality of light-emitting units 102, and a portion of the second electrode layer in the partition structure 10a is contiguous to a portion of the second electrode layer in the light-emitting region of each of the plurality of light-emitting units 102.

As the charge generation layer is spaced apart by the partition structure 10a, the transverse leakage current is not generated between the adjacent light-emitting units 102 even if the carrier mobility of the charge generation layer is high. In addition, the second electrode layer is not spaced apart by the partition structure 10a, and thus the light-emitting units 102 display normally.

In the embodiments of the present disclosure, the partition structure 10a formed by the first spacer h1 and the second spacer h2 is formed by a same patterning process, and the etching conditions are changes in the etching process in the patterning process. In some embodiments, the first definition layer 10221 and the third definition layer 10223 are made of SiO, and the second definition layer 10222 is made of SiN. The etching condition for etching the third definition layer 10223 to acquire the fifth definition pattern b5 and the sixth definition pattern b6 includes a mixture of trifluoromethane (CHF3), argon (Ar), and hydrogen (H2), and the etching condition for etching the second definition layer 10222 to acquire the third definition pattern b3 and the fourth definition pattern b4 includes a mixture of sulfur hexafluoride (SF6), oxygen (O2), and helium (He).

It can be further seen referring to FIG. 7 that the display panel further includes an organic insulative layer 104 between the plurality of light-emitting units 102 and the plurality of drive circuits 103. The connection electrode layer 10213 is connected to each of the plurality of drive circuits 103 through a second via in the organic insulative layer 104.

In general, the material of the organic insulative layer 104 is not affected by the wet etching process, and thus it is unnecessary to dispose the inorganic protection layer 105 on the side, away from the base substrate 101, of the organic insulative layer 104 in the case that the etching process in the patterning process used for the connection electrode layer 10213 and the protection electrode layer 10212 is the wet etching process. Thus, an additional patterning process for disposing the inorganic protection layer 105 is avoided, and the manufacturing difficulty of display panel 10 is reduced.

In the embodiments of the present disclosure, the drive circuit 103 includes a plurality of thin-film transistors and at least one storage capacitor. In some embodiments, the drive circuit 103 includes seven thin-film transistors and one storage capacitor. That is, the drive circuit 103 is a 7T1C circuit. Alternatively, the drive circuit 103 includes another number of thin-film transistors and another number of storage capacitors. The embodiments of the present disclosure do not limit the number of thin-film transistors and the number of storage capacitors in the drive circuit 103.

Each thin-film transistor includes a gate electrode, a source electrode, and a drain electrode. The plurality of thin-film transistors in the drive circuit 103 are connected to each other to drive the light-emitting units 102 to emit light.

In some embodiments, the drain electrode of one of the plurality of thin-film transistors in the drive circuit in the drive circuit is connected to the light-emitting unit 102. The drive circuit 103 in FIG. 7 represents the signal transmission portion in the drive circuit for transmitting signals. The signal transmission portion is disposed on a second source-drain electrode layer of the display panel.

In summary, the embodiments of the present disclosure provide a display panel. The display panel includes a base substrate, and a plurality of drive circuits and a plurality of light-emitting units on the base substrate. In addition, the display panel further includes a partition structure. The charge generation layer in the organic functional film layer is spaced apart by the partition structure, and the second electrode layer is not spaced apart by the partition structure, such that the display function of the display panel is ensured, the transverse leakage current is avoided, and the display effect is ensured.

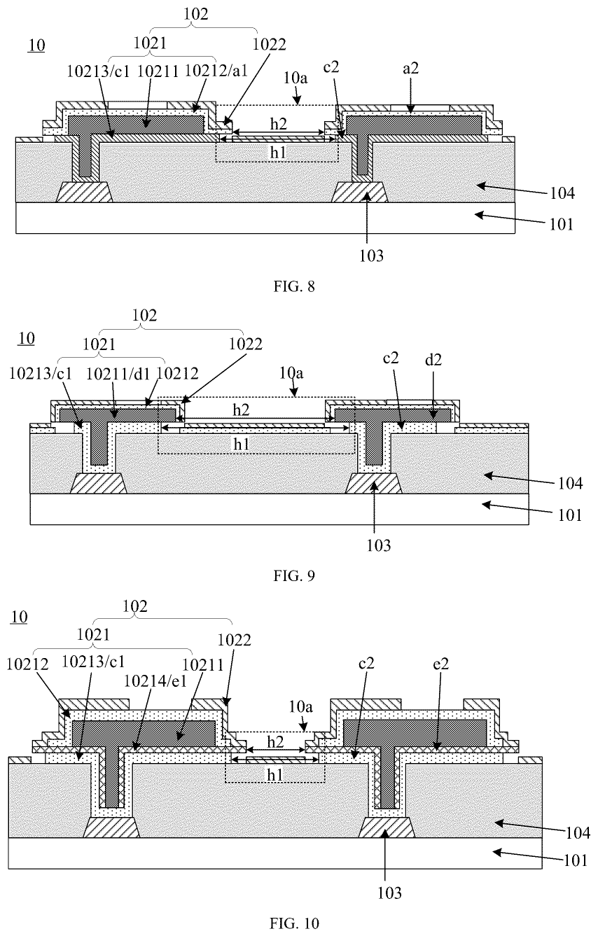

FIG. 8 is a schematic structural diagram of a display panel according to some embodiments of the present disclosures. Referring to FIG. 8, the display panel 10 includes a base substrate 101, a plurality of light-emitting units 102, and a plurality of drive circuits 103. Referring to FIG. 2, the base substrate 101 includes a display region 101a and a periphery region 101b surrounding the display region 101a.

In conjunction with FIG. 8 and FIG. 4, the plurality of light-emitting units 102 are disposed on a side of the base substrate 101 and disposed in the display region 101a. Each of the plurality of light-emitting units 102 includes a first electrode layer 1021, a pixel definition layer 1022, an organic functional film layer (not shown in the drawing), and a second electrode layer (not shown in the drawing) that are sequentially stacked in a direction away from the base substrate 101.

The first electrode layer 1021 includes a connection electrode layer 10213, a target electrode layer 10211, and a protection electrode layer 10212 that are stacked in the direction away from the base substrate 101. An orthographic projection of the protection electrode layer 10212 on the base substrate 101 and an orthographic projection of the connection electrode layer 10213 on the base substrate 101 both cover an orthographic projection of the target electrode layer 10211 on the base substrate 101 to avoid affecting the target electrode layer 10211 in the subsequent process and ensuring the yield of the target electrode layer 10211. The organic functional film layer at least includes a charge generation layer.

The plurality of drive circuits 103 are disposed between the base substrate 101 and the plurality of light-emitting units 102, and each of the plurality of drive circuits 103 is connected to a corresponding light-emitting unit 102 to provide a drive signal to the corresponding light-emitting unit 102.

Referring to FIG. 8, the display panel 10 further includes a partition structure 10a between light-emitting regions of any adjacent two of the plurality of light-emitting units 102. The connection electrode layer 10213 at least includes a first connection pattern c1 and a second connection pattern c2 that are spaced apart by a first spacer h1, and the protection electrode layer 10212 at least includes a first protection pattern a1 and a second protection pattern a2 that are spaced apart by a second spacer h2. The first spacer h1 is greater than the second spacer h2, and the partition structure 10a includes the first spacer h1 and the second spacer h2.

In the embodiments of the present disclosure, as the second spacer h2 between the first protection pattern a1 and the second protection pattern a2 in the protection electrode layer 10212 is less than the first spacer h1 between the first connection pattern c1 and the second connection pattern c2 in the connection electrode layer 10213, the protection pattern in the protection electrode layer 10212 covers the connection pattern in the connection electrode layer 10213, and the protection pattern includes a portion protruding from the connection pattern. That is, the connection electrode layer 10213 forms an undercut relative to the protection electrode layer 10212.

Furthermore, the protection electrode layer 10212 is farther away from the base substrate 101 than the connection electrode layer 10213, and thus some film layers subsequently formed on a side, away from the base substrate 101, of the pixel definition layer 1022 cannot be formed sequentially along the protection pattern and the connection pattern and are incontiguous at the partition structure 10a. Thus, the transverse leakage current due to the high carrier mobility of the film layer is avoided, and the luminous efficiency is ensured.

In the embodiments of the present disclosure, in general, various film layers on the side, away from the base substrate 101, of the pixel definition layer 1022 in the display panel 10 are increasingly not spaced apart by the partition structure 10a with increment of distances between the various film layers and the pixel definition layer 1022. Thus, the thicknesses of the connection electrode layer 10213 and the protection electrode layer 10212 are adjusted to adjust the partitioning effect of the partition structure 10a on the various film layers on the side, away from the base substrate 101, of the pixel definition layer 1022 in the display panel 10.

In some embodiments, as the second electrode layer is farther away from the pixel definition layer 1022 than the charge generation layer, the charge generation layer is prone to being spaced apart by the partition structure 10a than the second electrode layer. Thus, by adjusting the thicknesses of the protection electrode layer 10212 and the connection electrode layer 10213, the charge generation layer is spaced apart by the partition structure 10a, and the second electrode layer is not spaced apart by the partition structure 10a.

Illustratively, a portion of the charge generation layer in the partition structure 10a is incontiguous to a portion of the charge generation layer in a light-emitting region of each of the plurality of light-emitting units 102, and a portion of the second electrode layer in the partition structure 10a is contiguous to a portion of the second electrode layer in the light-emitting region of each of the plurality of light-emitting units 102. The second electrode layer acts as the anode of the light-emitting unit.

As the charge generation layer is spaced apart by the partition structure 10a, the transverse leakage current is not generated between the adjacent light-emitting units 102 even if the carrier mobility of the charge generation layer is high. In addition, the second electrode layer is not spaced apart by the partition structure 10a, and thus the light-emitting units 102 display normally.

In the embodiments of the present disclosure, the connection electrode layer 10213 and the protection electrode layer 10212 are made of different materials and are formed by a same patterning process, and the etching condition is changed in the etching process in the patterning process.

In some embodiments, the connection electrode layer 10213 is made of Mo, and the protection electrode layer 10212 is made of ITO. The etching process on the protection electrode layer 10212 and the etching process on the connection electrode layer 10213 are the wet etching process. The undercut of the connection electrode layer 10213 relative to the protection electrode layer 10212 is formed as the etching CD bias of the wet etching process on Mo is greater than the etching CD bias of the wet etching process on ITO.

Illustratively, the etching condition for etching the protection electrode layer 10212 to acquire the first protection pattern a1 and the second protection pattern a2 includes sulfuric acid (H2SO4), and the etching condition for etching the connection electrode layer 10213 to acquire the first connection pattern c1 and the second connection pattern c2 includes a mixture of nitric acid (HNO3), phosphoric acid (H3PO4), and acetic acid (CH3COOH).

In addition, as the material of upper film layer (the protection electrode layer 10212) of the partition structure 10a is a metal material but not an inorganic material, the protection electrode layer 10212 is not prone to breaking and is more resistant to the squeeze of the organic functional film layer, such that the partition structure 10a play a better partition role.

It can be further seen referring to FIG. 8 that the display panel further includes an organic insulative layer 104 between the plurality of light-emitting units 102 and the plurality of drive circuits 103. The connection electrode layer 10213 is connected to each of the plurality of drive circuits 103 through a second via in the organic insulative layer 104.

In general, the material of the organic insulative layer 104 is not affected by the wet etching process, and thus it is unnecessary to dispose the inorganic protection layer 105 on the side, away from the base substrate 101, of the organic insulative layer 104 in the case that the etching process in the patterning process used for the connection electrode layer 10213 is the wet etching process. Thus, an additional patterning process for disposing the inorganic protection layer 105 is avoided, and the manufacturing difficulty of display panel 10 is reduced.

In addition, as the material of the organic insulative layer 104 is not affected by the wet etching process, the organic insulative layer 104 is not over-etched in forming the connection electrode layer 10213 using the wet etching process, such that the high stability and control of the partition structure 10a are ensured.

In the embodiments of the present disclosure, the drive circuit 103 includes a plurality of thin-film transistors and at least one storage capacitor. In some embodiments, the drive circuit 103 includes seven thin-film transistors and one storage capacitor. That is, the drive circuit 103 is a 7T1C circuit. Alternatively, the drive circuit 103 includes another number of thin-film transistors and another number of storage capacitors. The embodiments of the present disclosure do not limit the number of thin-film transistors and the number of storage capacitors in the drive circuit 103.

Each thin-film transistor includes a gate electrode, a source electrode, and a drain electrode. The plurality of thin-film transistors in the drive circuit 103 are connected to each other to drive the light-emitting units 102 to emit light.

In some embodiments, the drain electrode of one of the plurality of thin-film transistors in the drive circuit in the drive circuit is connected to the light-emitting unit 102. The drive circuit 103 in FIG. 8 represents the signal transmission portion in the drive circuit for transmitting signals. The signal transmission portion is disposed on a second source-drain electrode layer of the display panel.

In summary, the embodiments of the present disclosure provide a display panel. The display panel includes a base substrate, and a plurality of drive circuits and a plurality of light-emitting units on the base substrate. In addition, the display panel further includes a partition structure. The charge generation layer in the organic functional film layer is spaced apart by the partition structure, and the second electrode layer is not spaced apart by the partition structure, such that the display function of the display panel is ensured, the transverse leakage current is avoided, and the display effect is ensured.

FIG. 9 is a schematic structural diagram of a display panel according to some embodiments of the present disclosures. Referring to FIG. 9, the display panel 10 includes a base substrate 101, a plurality of light-emitting units 102, and a plurality of drive circuits 103. Referring to FIG. 4, the base substrate 101 includes a display region 101a and a periphery region 101b surrounding the display region 101a.

In conjunction with FIG. 9 and FIG. 4, the plurality of light-emitting units 102 are disposed on a side of the base substrate 101 and disposed in the display region 101a. Each of the plurality of light-emitting units 102 includes a first electrode layer 1021, a pixel definition layer 1022, an organic functional film layer (not shown in the drawing), and a second electrode layer (not shown in the drawing) that are sequentially stacked in a direction away from the base substrate 101.

The first electrode layer 1021 includes a connection electrode layer 10213, a target electrode layer 10211, and a protection electrode layer 10212 that are stacked in the direction away from the base substrate 101. The organic functional film layer at least includes a charge generation layer.

The plurality of drive circuits 103 are disposed between the base substrate 101 and the plurality of light-emitting units 102, and each of the plurality of drive circuits 103 is connected to a corresponding light-emitting unit 102 to provide a drive signal to the corresponding light-emitting unit 102.

Referring to FIG. 9, the display panel 10 further includes a partition structure 10a between light-emitting regions of any adjacent two of the plurality of light-emitting units 102. The connection electrode layer 10213 at least includes a first connection pattern c1 and a second connection pattern c2 that are spaced apart by a first spacer h1, and the target electrode layer 10211 at least includes a first electrode pattern d1 and a second electrode pattern d2 that are spaced apart by a second spacer h2. The first spacer h1 is greater than the second spacer h2, and the partition structure 10a includes the first spacer h1 and the second spacer h2.

In the embodiments of the present disclosure, as the second spacer h2 between the first electrode pattern d1 and the second electrode pattern d2 in the target electrode layer 10211 is less than the first spacer h1 between the first connection pattern c1 and the second connection pattern c2 in the connection electrode layer 10213, the electrode pattern in the target electrode layer 10211 covers the connection pattern in the connection electrode layer 10213, and the electrode pattern includes a portion protruding from the connection pattern. That is, the connection electrode layer 10213 forms an undercut relative to the target electrode layer 10211.

Furthermore, the target electrode layer 10211 is farther away from the base substrate 101 than the connection electrode layer 10213, and thus some film layers subsequently formed on a side, away from the base substrate 101, of the pixel definition layer 1022 cannot be formed sequentially along the electrode pattern and the connection pattern and are incontiguous at the partition structure 10a. Thus, the transverse leakage current due to the high carrier mobility of the film layer is avoided, and the luminous efficiency is ensured.

In the embodiments of the present disclosure, in general, various film layers on the side, away from the base substrate 101, of the pixel definition layer 1022 in the display panel 10 are increasingly not spaced apart by the partition structure 10a with increment of distances between the various film layers and the pixel definition layer 1022. Thus, the thicknesses of the target electrode layer 10211 and the connection electrode layer 10213 are adjusted to adjust the partitioning effect of the partition structure 10a on the various film layers on the side, away from the base substrate 101, of the pixel definition layer 1022 in the display panel 10.

In some embodiments, as the second electrode layer is farther away from the pixel definition layer 1022 than the charge generation layer, the charge generation layer is prone to being spaced apart by the partition structure 10a than the second electrode layer. Thus, by adjusting the thicknesses of the target electrode layer 10211 and the connection electrode layer 10213, the charge generation layer is spaced apart by the partition structure 10a, and the second electrode layer is not spaced apart by the partition structure 10a.

Illustratively, a portion of the charge generation layer in the partition structure 10a is incontiguous to a portion of the charge generation layer in a light-emitting region of each of the plurality of light-emitting units 102, and a portion of the second electrode layer in the partition structure 10a is contiguous to a portion of the second electrode layer in the light-emitting region of each of the plurality of light-emitting units 102.

As the charge generation layer is spaced apart by the partition structure 10a, the transverse leakage current is not generated between the adjacent light-emitting units 102 even if the carrier mobility of the charge generation layer is high. In addition, the second electrode layer is not spaced apart by the partition structure 10a, and thus the light-emitting units 102 display normally. The second electrode layer acts as the anode of the light-emitting unit.

In addition, as the protection electrode layer 10212 is disposed on the side, away from the base substrate, of the partition structure 10a, the protection electrode layer 10212 is spaced apart by the partition structure 10a. In some embodiments, a portion of the protection electrode layer 10212 in the partition structure 10a is incontiguous to a portion of the protection electrode layer 10212 in the light-emitting region of each of the plurality of light-emitting units 102.

In the embodiments of the present disclosure, the connection electrode layer 10213 and the target electrode layer 10211 are made of different materials and are formed by a same patterning process, and the etching condition is changed in the etching process in the patterning process.

In some embodiments, the connection electrode layer 10213 is made of ITO, and the target electrode layer 10211 is made of a three-stack structure (denoted as Ti/Al/Ti) consisting of Ti, Al, and Ti. The etching process on the target electrode layer 10211 is the dry etching process, and the etching process on the connection electrode layer 10213 is the wet etching process. The undercut of the connection electrode layer 10213 relative to the target electrode layer 10211 is formed as the etching CD bias of the wet etching process on ITO is greater than the etching CD bias of the dry etching process on Ti/Al/Ti.

Illustratively, the etching condition for etching the target electrode layer 10211 to acquire the first electrode pattern d1 and the second electrode pattern d2 includes chlorine gas (Cl2), and the etching condition for etching the connection electrode layer 10213 to acquire the first connection pattern c1 and the second connection pattern c2 includes sulfuric acid (H2SO4).

In addition, as the material of upper film layer (the protection electrode layer 10212) of the partition structure 10a is a metal material but not an inorganic material, the protection electrode layer 10212 is not prone to breaking and is more resistant to the squeeze of the organic functional film layer, such that the partition structure 10a play a better partition role.

It can be further seen referring to FIG. 9 that the display panel further includes an organic insulative layer 104 between the plurality of light-emitting units 102 and the plurality of drive circuits 103. The connection electrode layer 10213 is connected to each of the plurality of drive circuits 103 through a second via in the organic insulative layer 104.

In general, the material of the organic insulative layer 104 is not affected by the wet etching process, and thus it is unnecessary to dispose the inorganic protection layer 105 on the side, away from the base substrate 101, of the organic insulative layer 104 in the case that the etching process in the patterning process used for the connection electrode layer 10213 is the wet etching process. Thus, an additional patterning process for disposing the inorganic protection layer 105 is avoided, and the manufacturing difficulty of display panel 10 is reduced.

In addition, as the material of the organic insulative layer 104 is not affected by the wet etching process, the organic insulative layer 104 is not over-etched in forming the connection electrode layer 10213 using the wet etching process, such that the high stability and control of the partition structure 10a are ensured.

In the embodiments of the present disclosure, the drive circuit 103 includes a plurality of thin-film transistors and at least one storage capacitor. In some embodiments, the drive circuit 103 includes seven thin-film transistors and one storage capacitor. That is, the drive circuit 103 is a 7T1C circuit. Alternatively, the drive circuit 103 includes another number of thin-film transistors and another number of storage capacitors. The embodiments of the present disclosure do not limit the number of thin-film transistors and the number of storage capacitors in the drive circuit 103.

Each thin-film transistor includes a gate electrode, a source electrode, and a drain electrode. The plurality of thin-film transistors in the drive circuit 103 are connected to each other to drive the light-emitting units 102 to emit light.

In some embodiments, the drain electrode of one of the plurality of thin-film transistors in the drive circuit in the drive circuit is connected to the light-emitting unit 102. The drive circuit 103 in FIG. 9 represents the signal transmission portion in the drive circuit for transmitting signals. The signal transmission portion is disposed on a second source-drain electrode layer of the display panel.

In summary, the embodiments of the present disclosure provide a display panel. The display panel includes a base substrate, and a plurality of drive circuits and a plurality of light-emitting units on the base substrate. In addition, the display panel further includes a partition structure. The charge generation layer in the organic functional film layer is spaced apart by the partition structure, and the second electrode layer is not spaced apart by the partition structure, such that the display function of the display panel is ensured, the transverse leakage current is avoided, and the display effect is ensured.

FIG. 10 is a schematic structural diagram of a display panel according to some embodiments of the present disclosures. Referring to FIG. 10, the display panel 10 includes a base substrate 101, a plurality of light-emitting units 102, and a plurality of drive circuits 103. Referring to FIG. 4, the base substrate 101 includes a display region 101a and a periphery region 101b surrounding the display region 101a.

In conjunction with FIG. 10 and FIG. 4, the plurality of light-emitting units 102 are disposed on a side of the base substrate 101 and disposed in the display region 101a. Each of the plurality of light-emitting units 102 includes a first electrode layer 1021, a pixel definition layer 1022, an organic functional film layer (not shown in the drawing), and a second electrode layer (not shown in the drawing) that are sequentially stacked in a direction away from the base substrate 101.

The first electrode layer 1021 includes a connection electrode layer 10213, an inorganic partition layer 10214, a target electrode layer 10211, and a protection electrode layer 10212 that are stacked in the direction away from the base substrate 101. The organic functional film layer at least includes a charge generation layer.

The plurality of drive circuits 103 are disposed between the base substrate 101 and the plurality of light-emitting units 102, and each of the plurality of drive circuits 103 is connected to a corresponding light-emitting unit 102 to provide a drive signal to the corresponding light-emitting unit 102.

Referring to FIG. 10, the display panel 10 further includes a partition structure 10a between light-emitting regions of any adjacent two of the plurality of light-emitting units 102. The connection electrode layer 10213 at least includes a first connection pattern c1 and a second connection pattern c2 that are spaced apart by a first spacer h1, and the inorganic partition layer 10214 at least includes a first insulative pattern e1 and a second insulative pattern e2 that are spaced apart by a second spacer h2. The first spacer h1 is greater than the second spacer h2, and the partition structure 10a includes the first spacer h1 and the second spacer h2.

In the embodiments of the present disclosure, as the second spacer h2 between the first insulative pattern e1 and the second insulative pattern e2 in the inorganic partition layer 10214 is less than the first spacer h1 between the first connection pattern c1 and the second connection pattern c2 in the connection electrode layer 10213, the insulative pattern in the inorganic partition layer 10214 covers the connection pattern in the connection electrode layer 10213, and the insulative pattern includes a portion protruding from the connection pattern. That is, the connection electrode layer 10213 forms an undercut relative to the inorganic partition layer 10214.

Furthermore, the inorganic partition layer 10214 is farther away from the base substrate 101 than the connection electrode layer 10213, and thus some film layers subsequently formed on a side, away from the base substrate 101, of the pixel definition layer 1022 cannot be formed sequentially along the electrode pattern and the connection pattern and are incontiguous at the partition structure 10a. Thus, the transverse leakage current due to the high carrier mobility of the film layer is avoided, and the luminous efficiency is ensured.

In the embodiments of the present disclosure, in general, various film layers on the side, away from the base substrate 101, of the pixel definition layer 1022 in the display panel 10 are increasingly not spaced apart by the partition structure 10a with increment of distances between the various film layers and the pixel definition layer 1022. Thus, the thicknesses of the inorganic partition layer 10214 and the connection electrode layer 10213 are adjusted to adjust the partitioning effect of the partition structure 10a on the various film layers on the side, away from the base substrate 101, of the pixel definition layer 1022 in the display panel 10.

In some embodiments, as the second electrode layer is farther away from the pixel definition layer 1022 than the charge generation layer, the charge generation layer is prone to being spaced apart by the partition structure 10a than the second electrode layer. Thus, by adjusting the thicknesses of the inorganic partition layer 10214 and the connection electrode layer 10213, the charge generation layer is spaced apart by the partition structure 10a, and the second electrode layer is not spaced apart by the partition structure 10a.

Illustratively, a portion of the charge generation layer in the partition structure 10a is incontiguous to a portion of the charge generation layer in a light-emitting region of each of the plurality of light-emitting units 102, and a portion of the second electrode layer in the partition structure 10a is contiguous to a portion of the second electrode layer in the light-emitting region of each of the plurality of light-emitting units 102. The second electrode layer acts as the anode of the light-emitting unit.

As the charge generation layer is spaced apart by the partition structure 10a, the transverse leakage current is not generated between the adjacent light-emitting units 102 even if the carrier mobility of the charge generation layer is high. In addition, the second electrode layer is not spaced apart by the partition structure 10a, and thus the light-emitting units 102 display normally.

In some embodiments, the protection electrode layer 10212, the inorganic partition layer 10214, and the connection electrode layer 10213 are formed by a same patterning process, and the etching condition is changed in the etching process in the patterning process.

In some embodiments, the protection electrode layer 10212 and the connection electrode layer 10213 are made of the same material. Illustratively, the protection electrode layer 10212 and the connection electrode layer 10213 are made of ITO. In addition, referring to FIG. 10, the inorganic partition layer 10214 is made of SiO or SiN. In this case, an orthographic projection of the protection electrode layer 10212 on the base substrate 101 is overlapped with an orthographic projection of the connection electrode layer 10213 on the base substrate 101.

The etching process on the target electrode layer 10211 is the dry etching process or the wet etching process, the etching process on the inorganic partition layer 10214 is the dry etching process, and the etching process on the connection electrode layer 10213 is the wet etching process. The undercut of the connection electrode layer 10213 relative to the inorganic partition layer 10214 is formed as the etching CD bias of the wet etching process on ITO is greater than the etching CD bias of the dry etching process on SiO or SiN.

Illustratively, the etching condition for etching the inorganic partition layer 10214 to acquire the first insulative pattern e1 and the second insulative pattern e2 includes a mixture of CHF3, Ar, and H2, and the etching condition for etching the connection electrode layer 10213 to acquire the first connection pattern c1 and the second connection pattern c2 includes H2SO4.

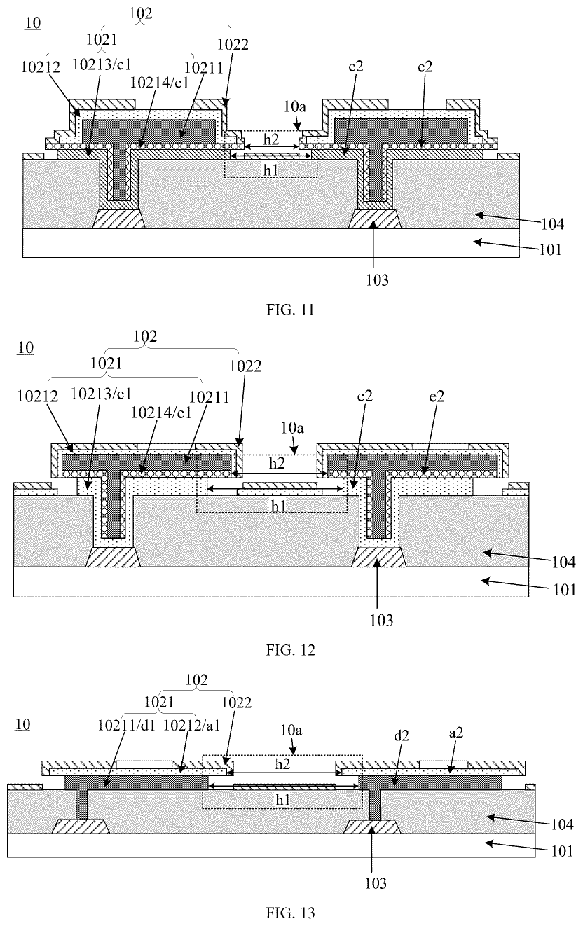

Alternatively, the protection electrode layer 10212 and the connection electrode layer 10213 are made of different materials. Illustratively, the protection electrode layer 10212 is made of ITO, and the connection electrode layer 10213 is made of Mo. In addition, the inorganic partition layer 10214 is made of SiO. In this case, referring to FIG. 11, the protection electrode layer 10212 at least includes a first protection pattern a1 and a second protection pattern a2 that are spaced apart by a fourth spacer h4. The fourth spacer h4 is less than the first spacer h1 and greater than the second spacer h2.

The etching process on the target electrode layer 10211 is the dry etching process or the wet etching process, the etching process on the inorganic partition layer 10214 is the dry etching process, and the etching process on the connection electrode layer 10213 is the wet etching process. The undercut of the connection electrode layer 10213 relative to the inorganic partition layer 10214 is formed as the etching CD bias of the wet etching process on Mo is greater than the etching CD bias of the dry etching process on SiO or SiN. In addition, the undercut of the connection electrode layer 10213 relative to the protection electrode layer 10212 is formed as the etching CD bias of the wet etching process on Mo is greater than the etching CD bias of the dry etching process (or the wet etching process) on ITO.

Illustratively, the etching condition for etching the inorganic partition layer 10214 to acquire the first insulative pattern e1 and the second insulative pattern e2 includes CHF3/Ar/H2, and the etching condition for etching the connection electrode layer 10213 to acquire the first connection pattern c1 and the second connection pattern c2 includes a mixture of HNO3, H3PO4, and CH3COOH.

In some embodiments, the protection electrode layer 10212, the inorganic partition layer 10214, and the connection electrode layer 10213 are formed by a same patterning process, and the etching condition is changed in the etching process in the patterning process.

In some embodiments, the connection electrode layer 10213 is made of ITO, the inorganic partition layer 10214 is made of SiO or SiN, and the target electrode layer 10211 is made of a three-stack structure (denoted as Ti/Al/Ti) consisting of Ti, Al, and Ti. In this case, referring to FIG. 12, an orthographic projection of the target electrode layer 10211 on the base substrate 101 is overlapped with an orthographic projection of the inorganic partition layer 10214 on the base substrate 101.

The etching process on the target electrode layer 10211 and the inorganic partition layer 10214 is the dry etching process, and the etching process on the connection electrode layer 10213 is the wet etching process. The undercut of the connection electrode layer 10213 relative to the inorganic partition layer 10214 is formed as the etching CD bias of the wet etching process on ITO is greater than the etching CD bias of the dry etching process on SiO or SiN and Ti/Al/Ti.

Illustratively, the etching condition for etching the inorganic partition layer 10214 to acquire the first insulative pattern e1 and the second insulative pattern e2 includes CHF3/Ar/H2, and the etching condition for etching the connection electrode layer 10213 to acquire the first connection pattern c1 and the second connection pattern c2 includes H2SO4.

In the embodiments of the present disclosure, as the protection electrode layer 10212 is disposed on the side, away from the base substrate, of the partition structure 10a, the protection electrode layer 10212 is spaced apart by the partition structure 10a. In some embodiments, a portion of the protection electrode layer 10212 in the partition structure 10a is incontiguous to a portion of the protection electrode layer 10212 in the light-emitting region of each of the plurality of light-emitting units 102.

It can be further seen referring to FIG. 10 to FIG. 12 that the display panel further includes an organic insulative layer 104 between the plurality of light-emitting units 102 and the plurality of drive circuits 103. The connection electrode layer 10213 is connected to each of the plurality of drive circuits 103 through a second via in the organic insulative layer 104.

In general, the material of the organic insulative layer 104 is not affected by the wet etching process, and thus it is unnecessary to dispose the inorganic protection layer 105 on the side, away from the base substrate 101, of the organic insulative layer 104 in the case that the etching process in the patterning process used for the connection electrode layer 10213 is the wet etching process. Thus, an additional patterning process for disposing the inorganic protection layer 105 is avoided, and the manufacturing difficulty of display panel 10 is reduced.

In addition, as the material of the organic insulative layer 104 is not affected by the wet etching process, the organic insulative layer 104 is not over-etched in forming the connection electrode layer 10213 using the wet etching process, such that the high stability and control of the partition structure 10a are ensured.

In the embodiments of the present disclosure, the drive circuit 103 includes a plurality of thin-film transistors and at least one storage capacitor. In some embodiments, the drive circuit 103 includes seven thin-film transistors and one storage capacitor. That is, the drive circuit 103 is a 7T1C circuit. Alternatively, the drive circuit 103 includes another number of thin-film transistors and another number of storage capacitors. The embodiments of the present disclosure do not limit the number of thin-film transistors and the number of storage capacitors in the drive circuit 103.

Each thin-film transistor includes a gate electrode, a source electrode, and a drain electrode. The plurality of thin-film transistors in the drive circuit 103 are connected to each other to drive the light-emitting units 102 to emit light.

In some embodiments, the drain electrode of one of the plurality of thin-film transistors in the drive circuit in the drive circuit is connected to the light-emitting unit 102. The drive circuit 103 in FIG. 10 to FIG. 12 represents the signal transmission portion in the drive circuit for transmitting signals. The signal transmission portion is disposed on a second source-drain electrode layer of the display panel.

In summary, the embodiments of the present disclosure provide a display panel. The display panel includes a base substrate, and a plurality of drive circuits and a plurality of light-emitting units on the base substrate. In addition, the display panel further includes a partition structure. The charge generation layer in the organic functional film layer is spaced apart by the partition structure, and the second electrode layer is not spaced apart by the partition structure, such that the display function of the display panel is ensured, the transverse leakage current is avoided, and the display effect is ensured.

FIG. 13 is a schematic structural diagram of a display panel according to some embodiments of the present disclosures. Referring to FIG. 13, the display panel 10 includes a base substrate 101, a plurality of light-emitting units 102, and a plurality of drive circuits 103. Referring to FIG. 4, the base substrate 101 includes a display region 101a and a periphery region 101b surrounding the display region 101a.

In conjunction with FIG. 13 and FIG. 4, the plurality of light-emitting units 102 are disposed on a side of the base substrate 101 and disposed in the display region 101a. Each of the plurality of light-emitting units 102 includes a first electrode layer 1021, a pixel definition layer 1022, an organic functional film layer (not shown in the drawing), and a second electrode layer (not shown in the drawing) that are sequentially stacked in a direction away from the base substrate 101.

The first electrode layer 1021 includes a target electrode layer 10211 and a protection electrode layer 10212 that are stacked in the direction away from the base substrate 101. The target electrode layer 10211 is manufactured by the wet etching process. The organic functional film layer at least includes a charge generation layer.

The plurality of drive circuits 103 are disposed between the base substrate 101 and the plurality of light-emitting units 102, and each of the plurality of drive circuits 103 is connected to a corresponding light-emitting unit 102 to provide a drive signal to the corresponding light-emitting unit 102.

Referring to FIG. 13, the display panel 10 further includes a partition structure 10a between light-emitting regions of any adjacent two of the plurality of light-emitting units 102. The target electrode layer 10211 at least includes a first electrode pattern d1 and a second electrode pattern d2 that are spaced apart by a first spacer h1, and the protection electrode layer 10212 at least includes a first protection pattern a1 and a second protection pattern a2 that are spaced apart by a second spacer h2. The first spacer h1 is greater than the second spacer h2, and the partition structure 10a includes the first spacer h1 and the second spacer h2.

In the embodiments of the present disclosure, as the second spacer h2 between the first protection pattern a1 and the second protection pattern a2 in the protection electrode layer 10212 is less than the first spacer h1 between the first electrode pattern d1 and the second electrode pattern d2 in the target electrode layer 10211, the protection pattern in the protection electrode layer 10212 covers the electrode pattern in the target electrode layer 10211, and the protection pattern includes a portion protruding from the electrode pattern. That is, the target electrode layer 10211 forms an undercut relative to the protection electrode layer 10212.

Furthermore, the protection electrode layer 10212 is farther away from the base substrate 101 than the target electrode layer 10211, and thus some film layers subsequently formed on a side, away from the base substrate 101, of the pixel definition layer 1022 cannot be formed sequentially along the protection pattern and the connection pattern and are incontiguous at the partition structure 10a. Thus, the transverse leakage current due to the high carrier mobility of the film layer is avoided, and the luminous efficiency is ensured.

In the embodiments of the present disclosure, in general, various film layers on the side, away from the base substrate 101, of the pixel definition layer 1022 in the display panel 10 are increasingly not spaced apart by the partition structure 10a with increment of distances between the various film layers and the pixel definition layer 1022. Thus, the thicknesses of the protection electrode layer 10212 and the target electrode layer 10211 are adjusted to adjust the partitioning effect of the partition structure 10a on the various film layers on the side, away from the base substrate 101, of the pixel definition layer 1022 in the display panel 10.

In some embodiments, as the second electrode layer is farther away from the pixel definition layer 1022 than the charge generation layer, the charge generation layer is prone to being spaced apart by the partition structure 10a than the second electrode layer. Thus, by adjusting the thicknesses of the target electrode layer 10211 and the protection electrode layer 10212, the charge generation layer is spaced apart by the partition structure 10a, and the second electrode layer is not spaced apart by the partition structure 10a.

Illustratively, a portion of the charge generation layer in the partition structure 10a is incontiguous to a portion of the charge generation layer in a light-emitting region of each of the plurality of light-emitting units 102, and a portion of the second electrode layer in the partition structure 10a is contiguous to a portion of the second electrode layer in the light-emitting region of each of the plurality of light-emitting units 102. The second electrode layer acts as the anode of the light-emitting unit.

As the charge generation layer is spaced apart by the partition structure 10a, the transverse leakage current is not generated between the adjacent light-emitting units 102 even if the carrier mobility of the charge generation layer is high. In addition, the second electrode layer is not spaced apart by the partition structure 10a, and thus the light-emitting units 102 display normally.

In some embodiments of the present disclosure, the target electrode layer 10211 and the protection electrode layer 10212 are formed by a same patterning process, and the etching condition is changed in the etching process in the patterning process.

In some embodiments, the target electrode layer 10211 is made of a three-stack structure (denoted as Mo/Al/Mo) consisting of Mo, Al, and Mo, and the protection electrode layer 10212 is made of ITO. The etching process on the protection electrode layer 10212 is the dry etching process, and the etching process on the target electrode layer 10211 is the wet etching process. The undercut of the target electrode layer 10211 relative to the protection electrode layer 10212 is formed as the etching CD bias of the wet etching process on Mo/Al/Mo is greater than the etching CD bias of the dry etching process on ITO.

Illustratively, the etching condition for etching the protection electrode layer 10212 to acquire the first protection pattern a1 and the second protection pattern a2 includes H2SO4, and the etching condition for etching the target electrode layer 10211 to acquire the first electrode pattern d1 and the second electrode pattern d2 includes a mixture of HNO3, H3PO4, and CH3COOH.

In addition, as the material of upper film layer (the protection electrode layer 10212) of the partition structure 10a is a metal material but not an inorganic material, the protection electrode layer 10212 is not prone to breaking and is more resistant to the squeeze of the organic functional film layer, such that the partition structure 10a play a better partition role.

It can be further seen referring to FIG. 13 that the display panel further includes an organic insulative layer 104 between the plurality of light-emitting units 102 and the plurality of drive circuits 103. The connection electrode layer 10213 is connected to each of the plurality of drive circuits 103 through a second via in the organic insulative layer 104.

In general, the material of the organic insulative layer 104 is not affected by the wet etching process, and thus it is unnecessary to dispose the inorganic protection layer 105 on the side, away from the base substrate 101, of the organic insulative layer 104 in the case that the etching process in the patterning process used for the connection electrode layer 10213 is the wet etching process. Thus, an additional patterning process for disposing the inorganic protection layer 105 is avoided, and the manufacturing difficulty of display panel 10 is reduced.

In addition, as the material of the organic insulative layer 104 is not affected by the wet etching process, the organic insulative layer 104 is not over-etched in forming the target electrode layer 10211 using the wet etching process, such that the high stability and control of the partition structure 10a are ensured.

In the embodiments of the present disclosure, the drive circuit 103 includes a plurality of thin-film transistors and at least one storage capacitor. In some embodiments, the drive circuit 103 includes seven thin-film transistors and one storage capacitor. That is, the drive circuit 103 is a 7T1C circuit. Alternatively, the drive circuit 103 includes another number of thin-film transistors and another number of storage capacitors. The embodiments of the present disclosure do not limit the number of thin-film transistors and the number of storage capacitors in the drive circuit 103.

Each thin-film transistor includes a gate electrode, a source electrode, and a drain electrode. The plurality of thin-film transistors in the drive circuit 103 are connected to each other to drive the light-emitting units 102 to emit light.

In some embodiments, the drain electrode of one of the plurality of thin-film transistors in the drive circuit in the drive circuit is connected to the light-emitting unit 102. The drive circuit 103 in FIG. 13 represents the signal transmission portion in the drive circuit for transmitting signals. The signal transmission portion is disposed on a second source-drain electrode layer of the display panel.

In summary, the embodiments of the present disclosure provide a display panel. The display panel includes a base substrate, and a plurality of drive circuits and a plurality of light-emitting units on the base substrate. In addition, the display panel further includes a partition structure. The charge generation layer in the organic functional film layer is spaced apart by the partition structure, and the second electrode layer is not spaced apart by the partition structure, such that the display function of the display panel is ensured, the transverse leakage current is avoided, and the display effect is ensured.

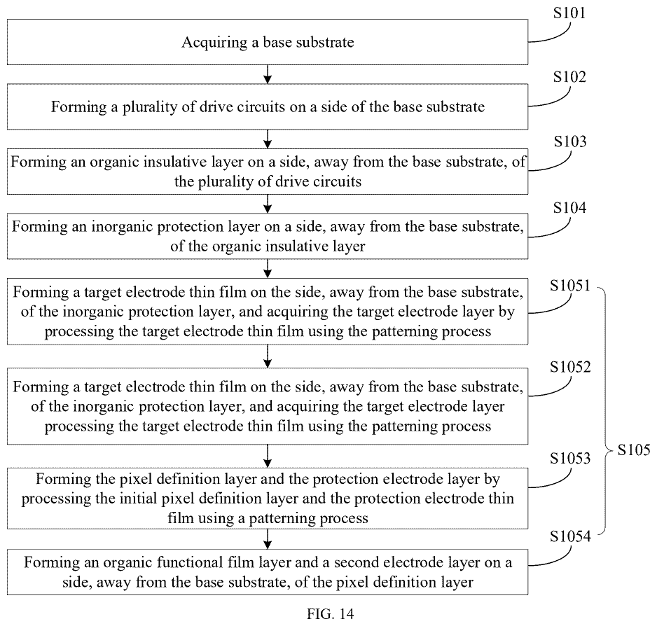

FIG. 14 is a flowchart of a method for manufacturing a display panel according to some embodiments of the present disclosure. Referring to FIG. 14, the method includes the following processes.

In S101, a base substrate is acquired.

In the embodiments of the present disclosure, the base substrate 101 includes a display region 101a and a periphery region 101b surrounding the display region 101a.

In S102, a plurality of drive circuits are formed on a side of the base substrate.

In the embodiments of the present disclosure, the drive circuit 103 includes a plurality of thin-film transistors and at least one storage capacitor. In some embodiments, the drive circuit 103 includes seven thin-film transistors and one storage capacitor. That is, the drive circuit 103 is a 7T1C circuit. Alternatively, the drive circuit 103 includes another number of thin-film transistors and another number of storage capacitors. The embodiments of the present disclosure do not limit the number of thin-film transistors and the number of storage capacitors in the drive circuit 103.

Various film layers of the thin-film transistors and the storage capacitors in the plurality of drive circuits 103 are formed on the side of the base substrate 101.

In S103, an organic insulative layer is formed on a side, away from the base substrate, of the plurality of drive circuits.

In the embodiments of the present disclosure, the process of forming the organic insulative layer 104 includes: forming an organic insulative thin film on the side, away from the base substrate 101, of the plurality of drive circuits 103, and processing the organic insulative thin film using a patterning process. The patterning process includes photoresist coating, exposing, developing, etching, and photoresist removing.

In some embodiments, the organic insulative layer 104 includes a second via. The second via exposes a signal output portion of the drive circuit 103, such that other subsequently formed film layers are connected to the drive circuit 103 through the second via to transmit drive signals.

In S104, an inorganic protection layer is formed on a side, away from the base substrate, of the organic insulative layer.

In the embodiments of the present disclosure, the process of forming the inorganic protection layer 105 includes: forming an inorganic protection thin film on the side, away from the base substrate 101, of the organic insulative layer 104, and processing the inorganic protection thin film using a patterning process. The patterning process includes photoresist coating, exposing, developing, etching, and photoresist removing.

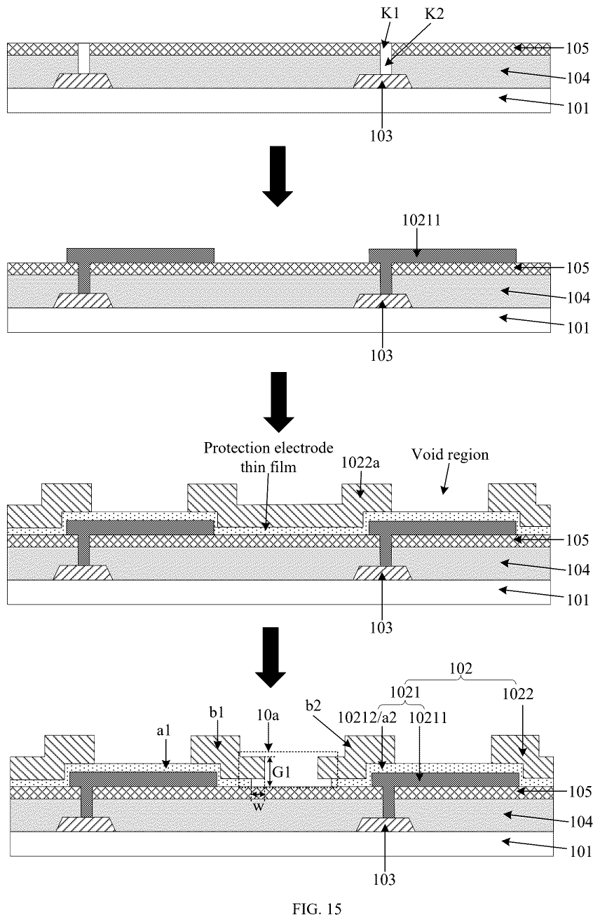

In some embodiments, referring to FIG. 15, the inorganic protection layer 105 includes a first via K1. The first via K1 exposes the signal output portion of the drive circuit 103, such that other subsequently formed film layers are connected to the drive circuit 103 through the first via K1 to transmit drive signals.

In S105, a plurality of light-emitting units are formed on a side, away from the base substrate, of the inorganic protection layer.

In the embodiments of the present disclosure, the plurality of light-emitting units 102 are disposed in the display region 101a and correspond to the plurality of drive circuits 103, and each of the plurality of drive circuits 103 is connected to a corresponding light-emitting unit 102 to provide a drive signal to the corresponding light-emitting unit 102.

Referring to FIG. 14, the process of forming the plurality of light-emitting units 102 includes the following process.

In S1051, a target electrode thin film is formed on the side, away from the base substrate, of the inorganic protection layer, and the target electrode layer is acquired by processing the target electrode thin film using the patterning process.

In the embodiments of the present disclosure, the target electrode thin film is made of a three-stack structure (denoted as Ti/Al/Ti) consisting of Ti, Al, and Ti. The etching process in the patterning process is the dry etching process, and the dry etching process uses Cl2.

Referring to FIG. 15, the target electrode layer 10211 includes a plurality of electrode patterns, and each electrode pattern is configured to form an anode of a light-emitting unit 102. In addition, each of the plurality of electrode patterns is connected to the drive circuit 103 through a first via K1 and a second via K2 to receive the drive signals provided by the drive circuit 103.

In S1052, a protection electrode thin film and a pixel definition thin film are formed on a side, away from the base substrate, of the target electrode layer, and an initial pixel definition layer is acquired by processing the pixel definition thin film using a patterning process.

In the embodiments of the present disclosure, the initial pixel definition layer 1022a includes a plurality of void regions, and each of the plurality of void regions exposes an electrode pattern, such that the subsequently formed organic functional film layer is in contact with the electrode patterns to achieve display.

In some embodiments, the protection electrode thin film is made of ITO. The pixel definition thin film includes a first thin film, a second thin film, and a third thin film that are stacked. The first thin film and the third thin film are made of SiO, and the second thin film is made of SiN. Alternatively, the pixel definition thin film includes a thin film layer of SiO or a thin film layer of SiN. The embodiments of the present disclosure do not limit the detailed structure and material of the pixel definition thin film.

In the case that the pixel definition thin film includes three thin film layer (denoted as SiO/SiN/SiO) consisting of SiO, SiN, and SiO, and initial pixel definition layer 1022a is acquired by processing the pixel definition thin film using the patterning process, SiO/SiN/SiO is etched using a mixture of CHF3, Ar, and H2 in the etching process in the patterning process. That is, SiO and SiN both are etched using the mixture of CHF3, Ar, and H2, and the SiO/SiN/SiO, that is, three layers need to be etched to acquire the void region.

In S1053, the pixel definition layer and the protection electrode layer are acquired by processing the initial pixel definition layer and the protection electrode thin film using a patterning process.

In the embodiments of the present disclosure, the initial pixel definition layer 1022a and the protection electrode thin film are processed by a same patterning process, and the etching condition is changed in the etching process in the patterning process.

In some embodiments, the mixture of CHF3, Ar, and H2 is used in etching the initial pixel definition layer 1022a, and H2SO4 is used in etching the protection electrode thin film. The undercut of the eventually formed protection electrode layer 10212 relative to the pixel definition layer 1022 is formed as the etching CD bias of the protection electrode thin film (ITO) is greater than the etching CD bias of the pixel definition layer 1022.

Referring to FIG. 15, the protection electrode layer 10212 at least includes a first protection pattern a1 and a second protection pattern a2 that are spaced apart by a first spacer h1, and the pixel definition layer 1022 at least includes a first definition pattern b1 and a second definition pattern b2 that are spaced apart by a second spacer h2. The first spacer h1 is greater than the second spacer h2, and the first spacer h1 and the second spacer h2 form the partition structure 10a.

In S1054, an organic functional film layer and a second electrode layer are formed on a side, away from the base substrate, of the pixel definition layer.

In the embodiments of the present disclosure, the organic functional film layer at least includes a charge generation layer, and the charge generation layer needs to be spaced apart as the carrier mobility of the charge generation layer is high.

As the pixel definition layer 1022 is farther away from the base substrate 101 than the protection electrode layer 10212, and thus the charge generation layer subsequently formed on a side, away from the base substrate 101, of the pixel definition layer 1022 cannot be formed sequentially along the protection pattern and the pixel pattern and are incontiguous at the partition structure 10a. Thus, the transverse leakage current due to the high carrier mobility of the film layer is avoided, and the luminous efficiency is ensured.

In general, various film layers on the side, away from the base substrate 101, of the pixel definition layer 1022 in the display panel 10 are increasingly not spaced apart by the partition structure 10a with increment of distances between the various film layers and the pixel definition layer 1022. Thus, the thicknesses of the protection electrode layer 10212 and the pixel definition layer 1022 are adjusted to adjust the partitioning effect of the partition structure 10a on the various film layers on the side, away from the base substrate 101, of the pixel definition layer 1022 in the display panel 10.

In some embodiments, as the second electrode layer is farther away from the pixel definition layer 1022 than the charge generation layer, the charge generation layer is prone to being spaced apart by the partition structure 10a than the second electrode layer. Thus, by adjusting the thicknesses of the protection electrode layer 10212 and the pixel definition layer 1022, the charge generation layer is spaced apart by the partition structure 10a, and the second electrode layer is not spaced apart by the partition structure 10a.

It should be noted that the patterning processes on the film layers prior to the organic insulative layer 104 and the film layers upon the pixel definition layer 1022 are required in each manufacturing method. For description of various manufacturing methods, a number of patterning processes from S104 to S1053 is used to measure the difficulty of the manufacturing method.

It can be seen from the above description of the processes that the patterning processes from S104 to S1053 are involved in the following processes. 1. In S104, the inorganic protection layer 105 (referred to as mask1) is acquired by processing the inorganic protection thin film. 2. In S1051, the target electrode layer 10211 (referred to as mask2) is acquired by processing the target electrode thin film. 3. In S1052, the initial pixel definition layer 1022a (referred to as mask3) is acquired by processing the pixel definition thin film. 4. In S1053, the pixel definition layer 1022 and the protection electrode layer 10212 (referred to as mask4) are acquired by processing the initial pixel definition layer 1022a and the protection electrode thin film. That is, the manufacturing method according to the embodiments of the present disclosure is a four-mask manufacturing method.

In summary, the embodiments of the present disclosure provide a method for manufacturing a display panel. The display panel acquired by the method includes a base substrate, and a plurality of drive circuits and a plurality of light-emitting units on the base substrate. In addition, the display panel further includes a partition structure. The charge generation layer in the organic functional film layer is spaced apart by the partition structure, and the second electrode layer is not spaced apart by the partition structure, such that the display function of the display panel is ensured, the transverse leakage current is avoided, and the display effect is ensured.

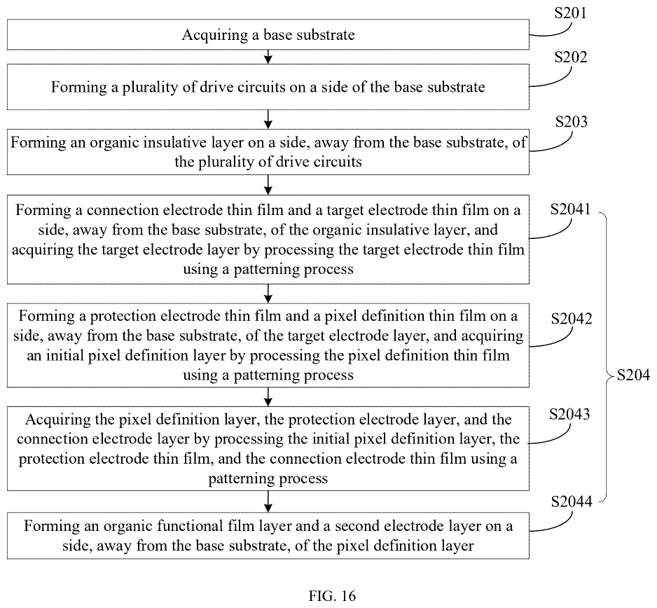

FIG. 16 is a flowchart of a method for manufacturing a display panel according to some embodiments of the present disclosure. Referring to FIG. 16, the method includes the following processes.

In S201, a base substrate is acquired.

In the embodiments of the present disclosure, the base substrate 101 includes a display region 101a and a periphery region 101b surrounding the display region 101a.

In S202, a plurality of drive circuits are formed on a side of the base substrate.

In the embodiments of the present disclosure, various film layers of the thin-film transistors and the storage capacitors in the plurality of drive circuits 103 are formed on the side of the base substrate 101.

In S203, an organic insulative layer is formed on a side, away from the base substrate, of the plurality of drive circuits.

In the embodiments of the present disclosure, the process of forming the organic insulative layer 104 includes: forming an organic insulative thin film on the side, away from the base substrate 101, of the plurality of drive circuits 103, and processing the organic insulative thin film using a patterning process. The patterning process includes photoresist coating, exposing, developing, etching, and photoresist removing.

In some embodiments, the organic insulative layer 104 includes a second via. The second via exposes a signal output portion of the drive circuit 103, such that other subsequently formed film layers are connected to the drive circuit 103 through the second via to transmit drive signals.

In S204, a plurality of light-emitting units 102 are formed on a side, away from the base substrate 101, of the organic insulative layer 104.

In the embodiments of the present disclosure, the plurality of light-emitting units 102 are disposed in the display region 101a and correspond to the plurality of drive circuits 103, and each of the plurality of drive circuits 103 is connected to a corresponding light-emitting unit 102 to provide a drive signal to the corresponding light-emitting unit 102.

Referring to FIG. 16, the process of forming the plurality of light-emitting units 102 includes the following process.

In S2041, a connection electrode thin film and a target electrode thin film are formed on a side, away from the base substrate, of the organic insulative layer, and the target electrode layer is acquired by processing the target electrode thin film using a patterning process.

In the embodiments of the present disclosure, at least part of the connection electrode thin film is within the second via K2, and is connected to a signal output portion of the drive circuit 103 exposed from the second via. In some embodiments, the connection electrode thin film is made of ITO, and the target electrode thin film is made of a three-stack structure (denoted as Ti/Al/Ti) consisting of Ti, Al, and Ti.

The connection electrode layer 10213 and the target electrode layer 10211 are processed by a same patterning process, and the etching condition in the etching process in the patterning process is adjusted. In some embodiments, upon formation of the connection electrode thin film and the target electrode thin film, the target electrode thin film is processed by a dry etching process, and the connection electrode thin film is processed by a wet etching process.

The undercut of the connection electrode layer 10213 relative to the target electrode layer 10211 is formed as the etching CD bias of the wet etching process on ITO is greater than the etching CD bias of the dry etching process on Ti/Al/Ti, and thus the partition structure 10a is formed.

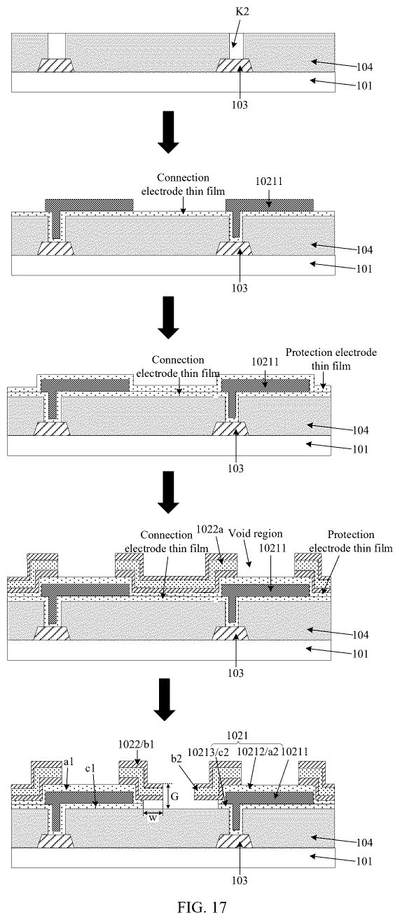

Referring to FIG. 17, the target electrode layer 10211 includes a plurality of electrode patterns, and each electrode pattern is configured to form an anode of a light-emitting unit 102. In addition, each of the plurality of electrode patterns is connected to the drive circuit 103 through the connection electrode thin film within the second via K2 to receive the drive signals provided by the drive circuit 103.

In S2042, a protection electrode thin film and a pixel definition thin film are formed on a side, away from the base substrate, of the target electrode layer, and an initial pixel definition layer is acquired by processing the pixel definition thin film using a patterning process.

In the embodiments of the present disclosure, the initial pixel definition layer 1022a includes a plurality of void regions, and each of the plurality of void regions exposes an electrode pattern, such that the subsequently formed organic functional film layer is in contact with the electrode patterns to achieve display.

In some embodiments, the protection electrode thin film is made of ITO. The pixel definition thin film includes a first thin film, a second thin film, and a third thin film that are stacked. The first thin film and the third thin film are made of SiO, and the second thin film is made of SiN.

In the case that the pixel definition thin film includes three thin film layer (denoted as SiO/SiN/SiO) consisting of SiO, SiN, and SiO, and initial pixel definition layer 1022a is acquired by processing the pixel definition thin film using the patterning process, SiO/SiN/SiO is etched using a mixture of CHF3, Ar, and H2 in the etching process in the patterning process. That is, SiO and SiN both are etched using the mixture of CHF3, Ar, and H2, and the SiO/SiN/SiO, that is, three layers need to be etched to acquire the void region.

In S2043, the pixel definition layer, the protection electrode layer, and the connection electrode layer are acquired by processing the initial pixel definition layer, the protection electrode thin film, and the connection electrode thin film using a patterning process.

In the embodiments of the present disclosure, the initial pixel definition layer 1022a, the protection electrode thin film, and the connection electrode thin film are processed by a same patterning process, and the etching condition is changed in the etching process in the patterning process.

In some embodiments, the mixture of CHF3, Ar, and H2 is used in etching the initial pixel definition layer 1022a, and H2SO4 is used in etching the protection electrode thin film. The undercut of the eventually formed protection electrode layer 10212 relative to the pixel definition layer 1022 is formed as the etching CD bias of the protection electrode thin film (ITO) is greater than the etching CD bias of the pixel definition layer 1022.

Referring to FIG. 17, the protection electrode layer 10212 at least includes a first protection pattern a1 and a second protection pattern a2 that are spaced apart by a first spacer h1, and the pixel definition layer 1022 at least includes a first definition pattern b1 and a second definition pattern b2 that are spaced apart by a second spacer h2. The first spacer h1 is greater than the second spacer h2, and the first spacer h1 and the second spacer h2 form the partition structure 10a.

Furthermore, referring to FIG. 17, for avoiding tandem of electrode patterns in the adjacent light-emitting units 102, the connection electrode layer 10213 at least includes a first connection pattern c1 and a second connection pattern c2 that are spaced apart by a third spacer h3. The partition structure 10a further includes the third spacer h3.

In the case that the connection electrode thin film and the protection electrode thin film both are made of ITO, the connection electrode thin film is also etched in the case that the protection electrode thin film is etched. In this case, the third spacer h3 is equal to the first spacer h1.

In the case that the connection electrode thin film is made of Mo, the etching condition is changed upon etching of the initial definition layer. For example, a mixture of HNO3, H3PO4, and CH3COOH is used in etching the connection electrode thin film. The undercut of the eventually formed connection electrode layer 10213 relative to the protection electrode layer 10212 is formed as the etching CD bias of the connection electrode thin film (Mo) is greater than the etching CD bias of the protection electrode layer 10212 (ITO).

In S2044, an organic functional film layer and a second electrode layer are formed on a side, away from the base substrate, of the pixel definition layer.

In the embodiments of the present disclosure, the organic functional film layer at least includes a charge generation layer. As the pixel definition layer 1022 is farther away from the base substrate 101 than the protection electrode layer 10212, and thus the charge generation layer subsequently formed on a side, away from the base substrate 101, of the pixel definition layer 1022 cannot be formed sequentially along the protection pattern and the pixel pattern and are incontiguous at the partition structure 10a. Thus, the transverse leakage current due to the high carrier mobility of the film layer is avoided, and the luminous efficiency is ensured.

In general, various film layers on the side, away from the base substrate 101, of the pixel definition layer 1022 in the display panel 10 are increasingly not spaced apart by the partition structure 10a with increment of distances between the various film layers and the pixel definition layer 1022. Thus, the thicknesses of the protection electrode layer 10212 and the pixel electrode layer are adjusted to adjust the partitioning effect of the partition structure 10a on the various film layers on the side, away from the base substrate 101, of the pixel definition layer 1022 in the display panel 10.

In some embodiments, as the second electrode layer is farther away from the pixel definition layer 1022 than the charge generation layer, the charge generation layer is prone to being spaced apart by the partition structure 10a than the second electrode layer. Thus, by adjusting the thicknesses of the protection electrode layer 10212 and the pixel electrode layer, the charge generation layer is spaced apart by the partition structure 10a, and the second electrode layer is not spaced apart by the partition structure 10a.

It should be noted that the patterning processes on the film layers prior to the organic insulative layer 104 and the film layers upon the pixel definition layer 1022 are required in each manufacturing method. For description of various manufacturing methods, a number of patterning processes from S2041 to S2043 is used to measure the difficulty of the manufacturing method.

It can be seen from the above description of the processes that the patterning processes from S2041 to S2043 are involved in the following processes. 1. In S2041, the target electrode layer 10211 (referred to as mask1) is acquired by processing the target electrode thin film. 2. In S2042, the initial pixel definition layer 1022a (referred to as mask2) is acquired by processing the pixel definition thin film. 3. In S2043, the pixel definition layer 1022, the protection electrode layer 10212, and the connection electrode layer 10213 (referred to as mask3) are acquired by processing the initial pixel definition layer 1022a, the protection electrode thin film, and the connection electrode thin film. That is, the manufacturing method according to the embodiments of the present disclosure is a three-mask manufacturing method.

In summary, the embodiments of the present disclosure provide a method for manufacturing a display panel. The display panel acquired by the method includes a base substrate, and a plurality of drive circuits and a plurality of light-emitting units on the base substrate. In addition, the display panel further includes a partition structure. The charge generation layer in the organic functional film layer is spaced apart by the partition structure, and the second electrode layer is not spaced apart by the partition structure, such that the display function of the display panel is ensured, the transverse leakage current is avoided, and the display effect is ensured.

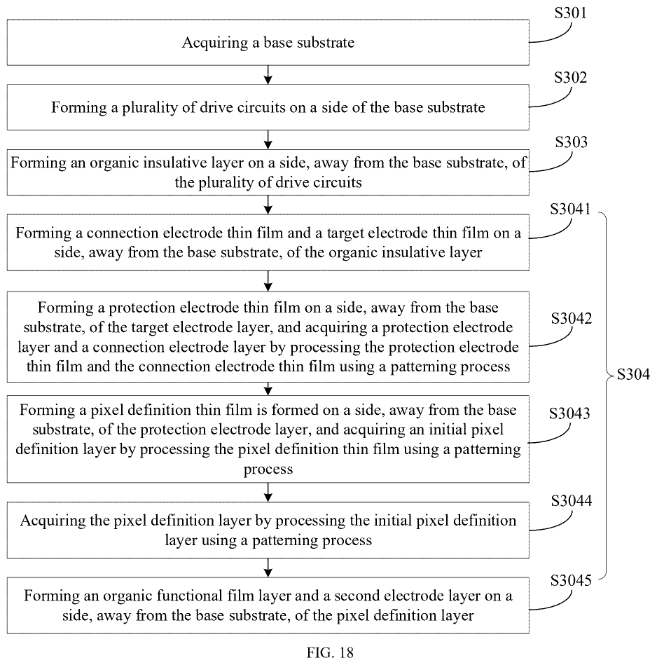

FIG. 18 is a flowchart of a method for manufacturing a display panel according to some embodiments of the present disclosure. Referring to FIG. 18, the method includes the following processes.

In S301, a base substrate is acquired.

In the embodiments of the present disclosure, the base substrate 101 includes a display region 101a and a periphery region 101b surrounding the display region 101a.

In S302, a plurality of drive circuits are formed on a side of the base substrate.

In the embodiments of the present disclosure, various film layers of the thin-film transistors and the storage capacitors in the plurality of drive circuits 103 are formed on the side of the base substrate 101.

In S303, an organic insulative layer is formed on a side, away from the base substrate, of the plurality of drive circuits.

In the embodiments of the present disclosure, the process of forming the organic insulative layer 104 includes: forming an organic insulative thin film on the side, away from the base substrate 101, of the plurality of drive circuits 103, and processing the organic insulative thin film using a patterning process. The patterning process includes photoresist coating, exposing, developing, etching, and photoresist removing.

In some embodiments, the organic insulative layer 104 includes a second via K2. The second via K2 exposes a signal output portion of the drive circuit 103, such that other subsequently formed film layers are connected to the drive circuit 103 through the second via K2 to transmit drive signals.

In S304, a plurality of light-emitting units are formed on a side, away from the base substrate, of the organic insulative layer.

In the embodiments of the present disclosure, the plurality of light-emitting units 102 are disposed in the display region 101a and correspond to the plurality of drive circuits 103, and each of the plurality of drive circuits 103 is connected to a corresponding light-emitting unit 102 to provide a drive signal to the corresponding light-emitting unit 102.

Referring to FIG. 18, the process of forming the plurality of light-emitting units 102 includes the following process.

In S3041, a connection electrode thin film and a target electrode thin film are formed on a side, away from the base substrate, of the organic insulative layer.

In the embodiments of the present disclosure, at least part of the connection electrode thin film is within the second via K2, and is connected to a signal output portion of the drive circuit 103 exposed from the second via K2. In some embodiments, the connection electrode thin film is made of ITO.

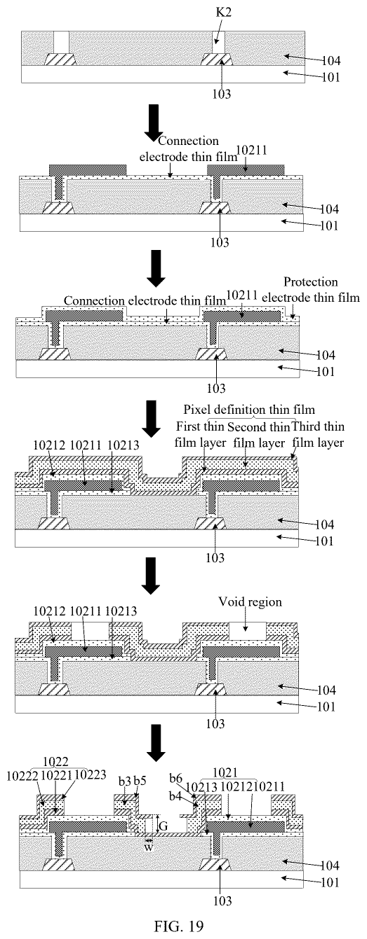

In addition, the process of forming the target electrode thin film includes: forming a target electrode thin film on a side, away from the base substrate 101, of the connection electrode thin film, and acquiring the target electrode layer 10211 by processing the target electrode thin film using a patterning process. Referring to FIG. 19, in the process of etching the target electrode thin film, the connection electrode thin under the target electrode thin film is not etched. That is, the connection electrode thin is a complete thin film.

In some embodiments, the target electrode thin film is made of a three-stack structure (denoted as Ti/Al/Ti) consisting of Ti, Al, and Ti. The etching process in the patterning process is the dry etching process, and Cl2 is used in the dry etching process.

Referring to FIG. 19, the target electrode layer 10211 includes a plurality of electrode patterns, and each electrode pattern is configured to form an anode of a light-emitting unit 102. In addition, each of the plurality of electrode patterns is connected to the drive circuit 103 through the connection electrode thin film within the second via K2 to receive the drive signals provided by the drive circuit 103.

In S3042, a protection electrode thin film is formed on a side, away from the base substrate, of the target electrode layer, and a protection electrode layer and a connection electrode layer are acquired by processing the protection electrode thin film and the connection electrode thin film using a patterning process.

In some embodiments, the protection electrode thin film is made of ITO. Upon formation of the protection electrode thin film, the protection electrode thin film and the connection electrode thin film are processed by a same patterning process. An orthographic projection of the acquired protection electrode layer 10212 on the base substrate 101 covers an orthographic projection of the target electrode layer 10211 on the base substrate 101, such that the protection electrode layer 10212 protects the target electrode layer 10211 in the subsequent process to avoid abnormal display caused by corrosion of the Al layer of the target electrode layer 10211 in the subsequent process.

In S3043, a pixel definition thin film is formed on a side, away from the base substrate, of the protection electrode layer, and an initial pixel definition layer is acquired by processing the pixel definition thin film using a patterning process.

In the embodiments of the present disclosure, the pixel definition thin film includes a first thin film, a second thin film, and a third thin film that are stacked. The first thin film and the third thin film are made of SiO, and the second thin film is made of SiN. In addition, the initial pixel definition layer 1022a includes a plurality of void regions, and each of the plurality of void regions exposes an electrode pattern, such that the subsequently formed organic functional film layer is in contact with the electrode patterns to achieve display.

In some embodiments, the pixel definition thin film includes a first thin film, a second thin film, and a third thin film that are stacked. The first thin film and the third thin film are made of SiO, and the second thin film is made of SiN.

In the case that the pixel definition thin film includes three thin film layer (denoted as SiO/SiN/SiO) consisting of SiO, SiN, and SiO, and initial pixel definition layer 1022a is acquired by processing the pixel definition thin film using the patterning process, SiO/SiN/SiO is etched using a mixture of CHF3, Ar, and H2 in the etching process in the patterning process. That is, SiO and SiN both are etched using the mixture of CHF3, Ar, and H2, and the SiO/SiN/SiO, that is, three layers need to be etched to acquire the void region.

In S3044, the pixel definition layer is acquired by processing the initial pixel definition layer using a patterning process.

In the embodiments of the present disclosure, referring to FIG. 19, a first definition layer 10221 in the pixel definition layer is a continuous film layer, a second definition layer 10222 at least includes a third definition pattern b3 and a fourth definition pattern b4 that are spaced apart by a first spacer h1, and a third definition layer 10223 at least includes a fifth definition pattern b5 and a sixth definition pattern b6 that are spaced apart by a second spacer h2. The first spacer h1 is greater than the second spacer h2, and the first spacer h1 and the second spacer h2 form the partition structure 10a.

For formation of the partition structure 10a, the etching process in the patterning process on the initial pixel definition layer 1022a includes two etching processes. In the first process, the mixture of CHF3, Ar, and H2 is used to etch the third thin film layer, and the etching process using the mixture of CHF3, Ar, and H2 is ended upon etching the second thin film layer (SiN) by controlling the etching time. In the second process, the second thin film layer is etched using the mixture of SF6, O2, and He.

The etching rate of SF6/O2/He to SiN is similar to the etching rate of CHF3/Ar/H2 to SiN, and the etching rate of SF6/O2/He to SiO is greatly different from the etching rate of CHF3/Ar/H2 to SiO. That is, the etching rate of SF6/O2/He to SiO is less, and the etching rate of CHF3/Ar/H2 to SiO is great. Thus, the immediate second thin film layer is etched using SF6/O2/He, and is retracted to form the undercut by adding the etching time, such that the partition structure 10a is acquired. In addition, even if the etching time is added, the etching damage on the first thin film layer is not great as the etching rate of SF6/O2/He to the first thin film layer is less. That is, the SiO in the lower layer is remained. The SiO in the lower layer in the partition structure 10a is remained to avoid puncture or partition of the second electrode layer due to a great height of the partition structure 10a.

In the embodiments of the present disclosure, the two patterning processes in S3043 and S3044 are performed because the void region of the pixel definition layer 1022 is acquired by etching SiO/SiN/SiO using the mixture of CHF3, Ar, and H2, the immediate SiN cannot be retracted to form the undercut to puncture or partition of the light-emitting material of the organic functional film layer in the void region or the second electrode layer, and the SiO in the lower layer in the partition structure 10a needs to be completely etched. In addition, the partition structure 10a needs to be etched by two processes, the SiN layer forms the undercut to partition, the SiO in the lower layer is not etched to avoid puncture or partition of the second electrode layer in the partition structure 10a due to a great height of the partition structure 10a.

In S3045, an organic functional film layer and a second electrode layer are formed on a side, away from the base substrate, of the pixel definition layer.

In the embodiments of the present disclosure, the organic functional film layer at least includes a charge generation layer. As the third definition layer 10223 in the pixel definition layer 1022 is farther away from the base substrate 101 than the second definition layer 10222, and thus the charge generation layer subsequently formed on the side, away from the base substrate 101, of the pixel definition layer 1022 cannot be formed sequentially along the definition pattern of the third definition layer 10223 and the definition pattern of the second definition layer 10222 and are incontiguous at the partition structure 10a. Thus, the transverse leakage current due to the high carrier mobility of the film layer is avoided, and the luminous efficiency is ensured.

In general, various film layers on the side, away from the base substrate 101, of the pixel definition layer 1022 in the display panel 10 are increasingly not spaced apart by the partition structure 10a with increment of distances between the various film layers and the pixel definition layer 1022. Thus, the thicknesses of the third definition layer 10223 and the second definition layer 10222 are adjusted to adjust the partitioning effect of the partition structure 10a on the various film layers on the side, away from the base substrate 101, of the pixel definition layer 1022 in the display panel 10.

In some embodiments, as the second electrode layer is farther away from the pixel definition layer 1022 than the charge generation layer, the charge generation layer is prone to being spaced apart by the partition structure 10a than the second electrode layer. Thus, by adjusting the thicknesses of the protection electrode layer 10212 and the pixel electrode layer, the charge generation layer is spaced apart by the partition structure 10a, and the second electrode layer is not spaced apart by the partition structure 10a.

It should be noted that the patterning processes on the film layers prior to the organic insulative layer 104 and the film layers upon the pixel definition layer 1022 are required in each manufacturing method. For description of various manufacturing methods, a number of patterning processes from S3041 to S3044 is used to measure the difficulty of the manufacturing method.

It can be seen from the above description of the processes that the patterning processes from S3041 to S3044 are involved in the following processes. 1. In S3041, the target electrode layer 10211 (referred to as mask1) is acquired by processing the target electrode thin film. 2. In S3042, the protection electrode layer 10212 and the connection electrode layer 10213 (referred to as mask2) are acquired by processing the protection electrode thin film and the connection electrode thin film. 3. In S3043, the initial pixel definition layer 1022a (referred to as mask3) is acquired by processing the pixel definition thin film. 4. In S3044, the pixel definition layer 1022 (referred to as mask4) is acquired by processing the initial pixel definition layer 1022a. That is, the manufacturing method according to the embodiments of the present disclosure is a four-mask manufacturing method.

In summary, the embodiments of the present disclosure provide a method for manufacturing a display panel. The display panel acquired by the method includes a base substrate, and a plurality of drive circuits and a plurality of light-emitting units on the base substrate. In addition, the display panel further includes a partition structure. The charge generation layer in the organic functional film layer is spaced apart by the partition structure, and the second electrode layer is not spaced apart by the partition structure, such that the display function of the display panel is ensured, the transverse leakage current is avoided, and the display effect is ensured.

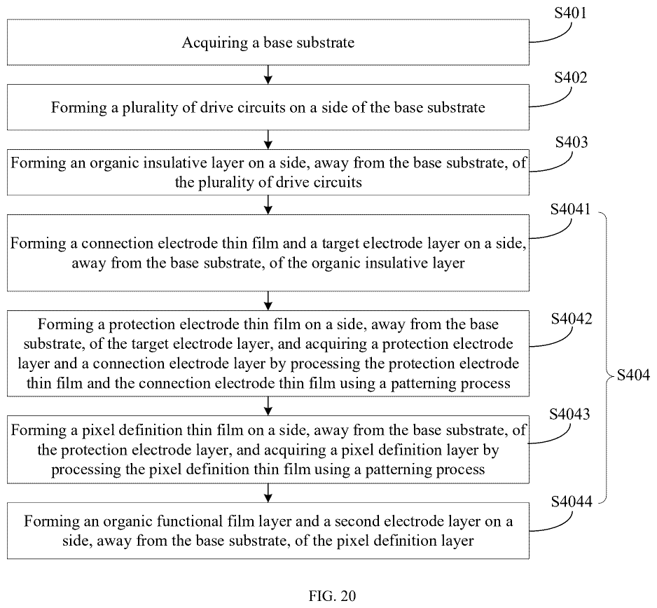

FIG. 20 is a flowchart of a method for manufacturing a display panel according to some embodiments of the present disclosure. Referring to FIG. 20, the method includes the following processes.

In S401, a base substrate is acquired.

In the embodiments of the present disclosure, the base substrate 101 includes a display region 101a and a periphery region 101b surrounding the display region 101a.

In S402, a plurality of drive circuits are formed on a side of the base substrate.

In the embodiments of the present disclosure, various film layers of the thin-film transistors and the storage capacitors in the plurality of drive circuits 103 are formed on the side of the base substrate 101.

In S403, an organic insulative layer is formed on a side, away from the base substrate, of the plurality of drive circuits.

In the embodiments of the present disclosure, the process of forming the organic insulative layer 104 includes: forming an organic insulative thin film on the side, away from the base substrate 101, of the plurality of drive circuits 103, and processing the organic insulative thin film using a patterning process. The patterning process includes photoresist coating, exposing, developing, etching, and photoresist removing.

In some embodiments, the organic insulative layer 104 includes a second via K2. The second via K2 exposes a signal output portion of the drive circuit 103, such that other subsequently formed film layers are connected to the drive circuit 103 through the second via K2 to transmit drive signals.

In S404, a plurality of light-emitting units are formed on a side, away from the base substrate, of the organic insulative layer.

In the embodiments of the present disclosure, the plurality of light-emitting units 102 are disposed in the display region 101a and correspond to the plurality of drive circuits 103, and each of the plurality of drive circuits 103 is connected to a corresponding light-emitting unit 102 to provide a drive signal to the corresponding light-emitting unit 102.

Referring to FIG. 20, the process of forming the plurality of light-emitting units 102 includes the following process.

In S4041, a connection electrode thin film and a target electrode layer are formed on a side, away from the base substrate, of the organic insulative layer.

In the embodiments of the present disclosure, at least part of the connection electrode thin film is within the second via K2, and is connected to a signal output portion of the drive circuit 103 exposed from the second via. In some embodiments, the connection electrode thin film is made of Mo.

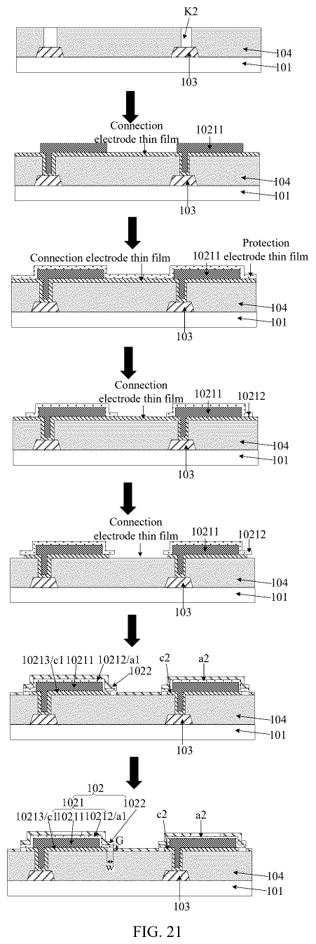

In addition, the process of forming the target electrode thin film includes: forming a target electrode thin film on a side, away from the base substrate 101, of the connection electrode thin film, and acquiring the target electrode layer 10211 by processing the target electrode thin film using a patterning process. Referring to FIG. 21, in the process of etching the target electrode thin film, the connection electrode thin under the target electrode thin film is not etched. That is, the connection electrode thin is a complete thin film.

In some embodiments, the target electrode thin film is made of a three-stack structure (denoted as Ti/Al/Ti) consisting of Ti, Al, and Ti. The etching process in the patterning process is the dry etching process, and Cl2 is used in the dry etching process.

Referring to FIG. 21, the target electrode layer 10211 includes a plurality of electrode patterns, and each electrode pattern is configured to form an anode of a light-emitting unit 102. In addition, each of the plurality of electrode patterns is connected to the drive circuit 103 through the connection electrode thin film within the second via K2 to receive the drive signals provided by the drive circuit 103.

In S4042, a protection electrode thin film is formed on a side, away from the base substrate, of the target electrode layer, and a protection electrode layer and a connection electrode layer are acquired by processing the protection electrode thin film and the connection electrode thin film using a patterning process.

In some embodiments, the protection electrode thin film is made of ITO. Upon formation of the protection electrode thin film, the protection electrode thin film and the connection electrode thin film are processed by a same patterning process. An orthographic projection of the acquired protection electrode layer 10212 on the base substrate 101 covers an orthographic projection of the target electrode layer 10211 on the base substrate 101, such that the protection electrode layer 10212 protects the target electrode layer 10211 in the subsequent process to avoid abnormal display caused by corrosion of the Al layer of the target electrode layer 10211 in the subsequent process.

Referring to FIG. 21, the connection electrode layer 10213 at least includes a first connection pattern c1 and a second connection pattern c2 that are spaced apart by a first spacer h1, and the protection electrode layer 10212 at least includes a first protection pattern a1 and a second protection pattern a2 that are spaced apart by a second spacer h2. The first spacer h1 is greater than the second spacer h2, and the partition structure 10a includes the first spacer h1 and the second spacer h2.

In some embodiments, in the etching process in the patterning process on the protection electrode thin film and the connection electrode thin film, the protection electrode thin film (ITO) is first etched by the wet etching process or the dry etching process, and then the connection electrode thin film (Mo) is etched by the wet etching process. H2SO4 is used to etch the protection electrode thin film, and a mixture of HNO3, H3PO4, and CH3COOH is used to etch the connection electrode thin film.

The undercut of the connection electrode layer 10213 relative to the protection electrode layer 10212 is formed as the etching CD bias of the wet etching process on Mo is greater than the etching CD bias of wet etching process on ITO.

In the embodiments of the present disclosure, as the material of the organic insulative layer 104 is not affected by the wet etching process, the organic insulative layer 104 is not over-etched in forming the connection electrode layer 10213 using the wet etching process, such that the high stability and control of the partition structure 10a are ensured.

In some embodiments, a width of the undercut of the partition structure 10a is less than 0.5 μm, that is, w<0.5 μm. A height of the partition structure 10a is less than 200 nm, that is, G<200 nm. Based on the stable and controllable width of the undercut and the height of the partition structure 10a, the charge generation layer is spaced apart by the partition structure 10a, and the second electrode layer is not spaced apart by the partition structure 10a.

In S4043, a pixel definition thin film is formed on a side, away from the base substrate, of the protection electrode layer, and a pixel definition layer is acquired by processing the pixel definition thin film using a patterning process.

In the embodiments of the present disclosure, referring to FIG. 21, the formed pixel definition thin film is spaced apart by the partition structure 10a. The void in the pixel definition layer 1022 is formed by the same patterning process. Each of the plurality of void regions exposes an electrode pattern, such that the subsequently formed organic functional film layer is in contact with the electrode patterns to achieve display.

In some embodiments, the pixel definition thin film includes a first thin film, a second thin film, and a third thin film that are stacked. The first thin film and the third thin film are made of SiO, and the second thin film is made of SiN. Alternatively, the pixel definition thin film includes a thin film layer of SiO or a thin film layer of SiN. The embodiments of the present disclosure do not limit the detailed structure and material of the pixel definition thin film.

In the case that the pixel definition thin film includes three thin film layer (denoted as SiO/SiN/SiO) consisting of SiO, SiN, and SiO, and initial pixel definition layer 1022a is acquired by processing the pixel definition thin film using the patterning process, SiO/SiN/SiO is etched using a mixture of CHF3, Ar, and H2 in the etching process in the patterning process. That is, SiO and SiN both are etched using the mixture of CHF3, Ar, and H2, and the SiO/SiN/SiO, that is, three layers need to be etched to acquire the void region.

In S4044, an organic functional film layer and a second electrode layer are formed on a side, away from the base substrate, of the pixel definition layer.

In the embodiments of the present disclosure, the organic functional film layer at least includes a charge generation layer, and the charge generation layer needs to be spaced apart as the carrier mobility of the charge generation layer is high. Based on the partition structure 10a, the charge generation layer subsequently formed on a side, away from the base substrate 101, of the pixel definition layer 1022 is spaced apart at the partition structure 10a. Thus, the transverse leakage current due to the high carrier mobility of the film layer is avoided, and the luminous efficiency is ensured.

In general, various film layers on the side, away from the base substrate 101, of the pixel definition layer 1022 in the display panel 10 are increasingly not spaced apart by the partition structure 10a with increment of distances between the various film layers and the pixel definition layer 1022. Thus, the thicknesses of the connection electrode layer 10213 and the protection electrode layer 10212 are adjusted to adjust the partitioning effect of the partition structure 10a on the various film layers on the side, away from the base substrate 101, of the pixel definition layer 1022 in the display panel 10.

In some embodiments, as the second electrode layer is farther away from the pixel definition layer 1022 than the charge generation layer, the charge generation layer is prone to being spaced apart by the partition structure 10a than the second electrode layer. Thus, by adjusting the thicknesses of the connection electrode layer 10213 and the protection electrode layer 10212, the charge generation layer is spaced apart by the partition structure 10a, and the second electrode layer is not spaced apart by the partition structure 10a.

It should be noted that the patterning processes on the film layers prior to the organic insulative layer 104 and the film layers upon the pixel definition layer 1022 are required in each manufacturing method. For description of various manufacturing methods, a number of patterning processes from S4041 to S4043 is used to measure the difficulty of the manufacturing method.

It can be seen from the above description of the processes that the patterning processes from S4041 to S4043 are involved in the following processes. 1. In S4041, the target electrode layer 10211 (referred to as mask1) is acquired by processing the target electrode thin film. 2. In S4042, the protection electrode layer 10212 and the connection electrode layer 10213 (referred to as mask2) are acquired by processing the protection electrode thin film and the connection electrode thin film. 3. In S4043, the pixel definition layer 1022 (referred to as mask3) is acquired by processing the initial pixel definition layer. That is, the manufacturing method according to the embodiments of the present disclosure is a three-mask manufacturing method.

In summary, the embodiments of the present disclosure provide a method for manufacturing a display panel. The display panel acquired by the method includes a base substrate, and a plurality of drive circuits and a plurality of light-emitting units on the base substrate. In addition, the display panel further includes a partition structure. The charge generation layer in the organic functional film layer is spaced apart by the partition structure, and the second electrode layer is not spaced apart by the partition structure, such that the display function of the display panel is ensured, the transverse leakage current is avoided, and the display effect is ensured.

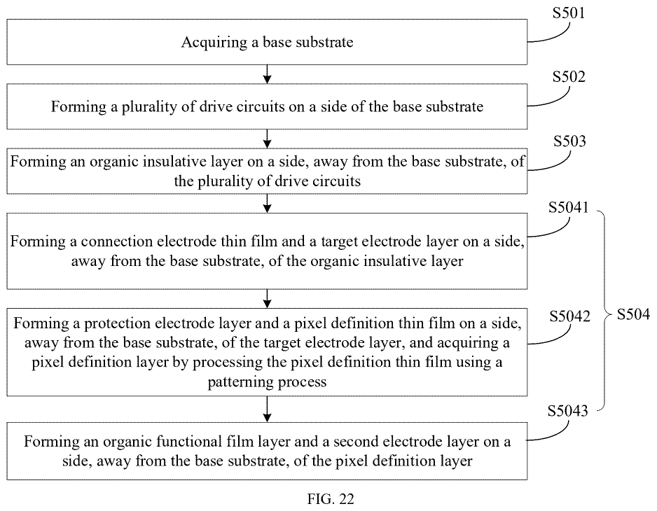

FIG. 22 is a flowchart of a method for manufacturing a display panel according to some embodiments of the present disclosure. Referring to FIG. 22, the method includes the following processes.

In S501, a base substrate is acquired.

In the embodiments of the present disclosure, the base substrate 101 includes a display region 101a and a periphery region 101b surrounding the display region 101a.

In S502, a plurality of drive circuits are formed on a side of the base substrate.

In the embodiments of the present disclosure, various film layers of the thin-film transistors and the storage capacitors in the plurality of drive circuits 103 are formed on the side of the base substrate 101.

In S503, an organic insulative layer is formed on a side, away from the base substrate, of the plurality of drive circuits.

In the embodiments of the present disclosure, the process of forming the organic insulative layer 104 includes: forming an organic insulative thin film on the side, away from the base substrate 101, of the plurality of drive circuits 103, and processing the organic insulative thin film using a patterning process. The patterning process includes photoresist coating, exposing, developing, etching, and photoresist removing.

In some embodiments, the organic insulative layer 104 includes a second via K2. The second via K2 exposes a signal output portion of the drive circuit 103, such that other subsequently formed film layers are connected to the drive circuit 103 through the second via K2 to transmit drive signals.

In S504, a plurality of light-emitting units are formed on a side, away from the base substrate, of the organic insulative layer.

In the embodiments of the present disclosure, the plurality of light-emitting units 102 are disposed in the display region 101a and correspond to the plurality of drive circuits 103, and each of the plurality of drive circuits 103 is connected to a corresponding light-emitting unit 102 to provide a drive signal to the corresponding light-emitting unit 102.

Referring to FIG. 22, the process of forming the plurality of light-emitting units 102 includes the following process.

In S5041, a connection electrode thin film and a target electrode layer are formed on a side, away from the base substrate, of the organic insulative layer.

In the embodiments of the present disclosure, at least part of the connection electrode thin film is within the second via K2, and is connected to a signal output portion of the drive circuit 103 exposed from the second via. In some embodiments, the connection electrode thin film is made of ITO or Mo.

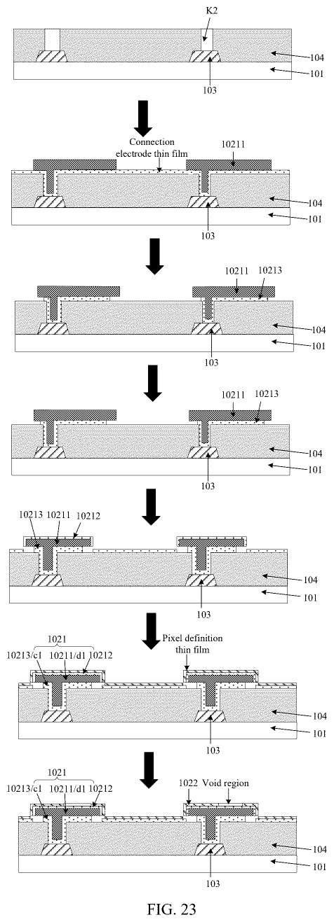

In addition, the process of forming the target electrode thin film includes: forming a target electrode thin film on a side, away from the base substrate 101, of the connection electrode thin film, and acquiring the target electrode layer 10211 by processing the target electrode thin film using a patterning process. Referring to FIG. 23, in the process of etching the target electrode thin film, the connection electrode thin under the target electrode thin film is not etched. That is, the connection electrode thin is a complete thin film.

In some embodiments, the target electrode thin film is made of a three-stack structure (denoted as Ti/Al/Ti) consisting of Ti, Al, and Ti. The etching process in the patterning process is the dry etching process, and Cl2 is used in the dry etching process.

Referring to FIG. 23, the connection electrode layer 10213 at least includes a first connection pattern c1 and a second connection pattern c2 that are spaced apart by a first spacer h1, and the target electrode layer 10211 at least includes a first electrode pattern d1 and a second electrode pattern d2 that are spaced apart by a second spacer h2. The first spacer h1 is greater than the second spacer h2, and the partition structure 10a includes the first spacer h1 and the second spacer h2. Each electrode pattern in the target electrode layer 10211 is configured to form an anode of a light-emitting unit 102. In addition, each electrode pattern is connected to the drive circuit 103 through the connection electrode thin film within the second via K2 to receive the drive signals provided by the drive circuit 103.

In S5042, a protection electrode layer and a pixel definition thin film are formed on a side, away from the base substrate, of the target electrode layer, and a pixel definition layer is acquired by processing the pixel definition thin film using a patterning process.

In the embodiments of the present disclosure, referring to FIG. 23, based on the partition structure 10a, the formed protection electrode layer 10212 is directly spaced apart by the partition structure 10a. That is, a portion of the protection electrode layer 10212 in the partition structure 10a is incontiguous to a portion of the protection electrode layer 10212 above the target electrode layer 10211.

Furthermore, based on the partition structure 10a, the formed pixel definition thin film is directly spaced apart by the partition structure 10a. That is, a portion of the pixel definition thin film in the partition structure 10a is incontiguous to a portion of the pixel definition thin film above the target electrode.

Thus, the void in the pixel definition layer 1022 is formed by the same patterning process. Each of the plurality of void regions exposes an electrode pattern, such that the subsequently formed organic functional film layer is in contact with the electrode patterns to achieve display.

In some embodiments, the pixel definition thin film includes a first thin film, a second thin film, and a third thin film that are stacked. The first thin film and the third thin film are made of SiO, and the second thin film is made of SiN. Alternatively, the pixel definition thin film includes a thin film layer of SiO or a thin film layer of SiN. The embodiments of the present disclosure do not limit the detailed structure and material of the pixel definition thin film.

In the case that the pixel definition thin film includes three thin film layer (denoted as SiO/SiN/SiO) consisting of SiO, SiN, and SiO, and initial pixel definition layer 1022a is acquired by processing the pixel definition thin film using the patterning process, SiO/SiN/SiO is etched using a mixture of CHF3, Ar, and H2 in the etching process in the patterning process. That is, SiO and SiN both are etched using the mixture of CHF3, Ar, and H2, and the SiO/SiN/SiO, that is, three layers need to be etched to acquire the void region.

In S5043, an organic functional film layer and a second electrode layer are formed on a side, away from the base substrate, of the pixel definition layer.

In the embodiments of the present disclosure, the organic functional film layer at least includes a charge generation layer. Based on the partition structure 10a, the charge generation layer subsequently formed on a side, away from the base substrate 101, of the pixel definition layer 1022 is spaced apart at the partition structure 10a. Thus, the transverse leakage current due to the high carrier mobility of the film layer is avoided, and the luminous efficiency is ensured.

In general, various film layers on the side, away from the base substrate 101, of the pixel definition layer 1022 in the display panel 10 are increasingly not spaced apart by the partition structure 10a with increment of distances between the various film layers and the pixel definition layer 1022. Thus, the thicknesses of the connection electrode layer 10213 and the target electrode layer 10211 are adjusted to adjust the partitioning effect of the partition structure 10a on the various film layers on the side, away from the base substrate 101, of the pixel definition layer 1022 in the display panel 10.

In some embodiments, as the second electrode layer is farther away from the pixel definition layer 1022 than the charge generation layer, the charge generation layer is prone to being spaced apart by the partition structure 10a than the second electrode layer. Thus, by adjusting the thicknesses of the connection electrode layer 10213 and the target electrode layer 10211, the charge generation layer is spaced apart by the partition structure 10a, and the second electrode layer is not spaced apart by the partition structure 10a.

It should be noted that the patterning processes on the film layers prior to the organic insulative layer 104 and the film layers upon the pixel definition layer 1022 are required in each manufacturing method. For description of various manufacturing methods, a number of patterning processes from S5041 to S5042 is used to measure the difficulty of the manufacturing method.

It can be seen from the above description of the processes that the patterning processes from S5041 to S5042 are involved in the following processes. 1. In S5041, the target electrode layer 10211 and the connection electrode layer 10213 (referred to as mask1) are acquired by processing the target electrode thin film and the connection electrode thin film. 2. In S5042, the pixel definition layer 1022 (referred to as mask2) is acquired by processing the initial pixel definition layer. That is, the manufacturing method according to the embodiments of the present disclosure is a two-mask manufacturing method.

In summary, the embodiments of the present disclosure provide a method for manufacturing a display panel. The display panel acquired by the method includes a base substrate, and a plurality of drive circuits and a plurality of light-emitting units on the base substrate. In addition, the display panel further includes a partition structure. The charge generation layer in the organic functional film layer is spaced apart by the partition structure, and the second electrode layer is not spaced apart by the partition structure, such that the display function of the display panel is ensured, the transverse leakage current is avoided, and the display effect is ensured.

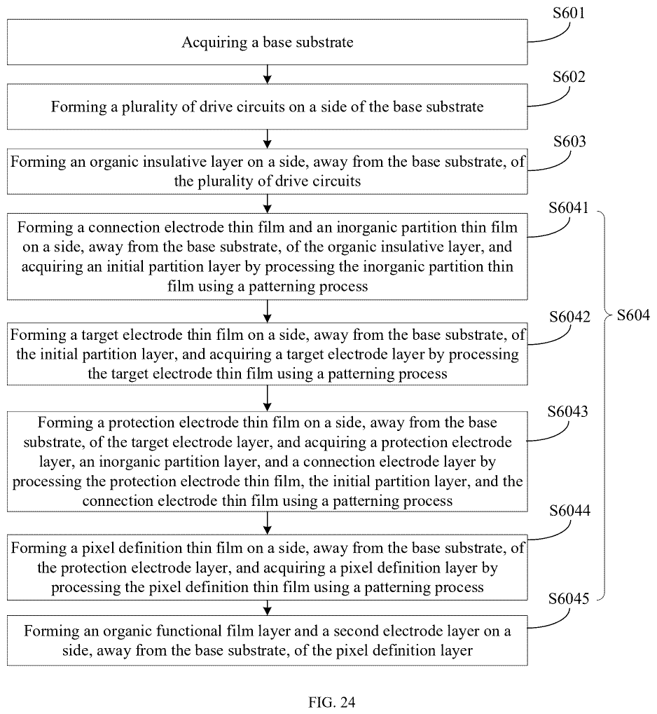

FIG. 24 is a flowchart of a method for manufacturing a display panel according to some embodiments of the present disclosure. Referring to FIG. 24, the method includes the following processes.

In S601, a base substrate is acquired.

In the embodiments of the present disclosure, the base substrate 101 includes a display region 101a and a periphery region 101b surrounding the display region 101a.

In S602, a plurality of drive circuits are formed on a side of the base substrate.

In the embodiments of the present disclosure, various film layers of the thin-film transistors and the storage capacitors in the plurality of drive circuits 103 are formed on the side of the base substrate 101.

In S603, an organic insulative layer is formed on a side, away from the base substrate, of the plurality of drive circuits.

In the embodiments of the present disclosure, the process of forming the organic insulative layer 104 includes: forming an organic insulative thin film on the side, away from the base substrate 101, of the plurality of drive circuits 103, and processing the organic insulative thin film using a patterning process. The patterning process includes photoresist coating, exposing, developing, etching, and photoresist removing.

In some embodiments, the organic insulative layer 104 includes a second via K2. The second via K2 exposes a signal output portion of the drive circuit 103, such that other subsequently formed film layers are connected to the drive circuit 103 through the second via K2 to transmit drive signals.

In S604, a plurality of light-emitting units are formed on a side, away from the base substrate, of the organic insulative layer.

In the embodiments of the present disclosure, the plurality of light-emitting units 102 are disposed in the display region 101a and correspond to the plurality of drive circuits 103, and each of the plurality of drive circuits 103 is connected to a corresponding light-emitting unit 102 to provide a drive signal to the corresponding light-emitting unit 102.

Referring to FIG. 24, the process of forming the plurality of light-emitting units 102 includes the following process.

In S6041, a connection electrode thin film and an inorganic partition thin film are formed on a side, away from the base substrate, of the organic insulative layer, and an initial partition layer is acquired by processing the inorganic partition thin film using a patterning process.

In the embodiments of the present disclosure, at least part of the connection electrode thin film is within the second via, and is connected to a signal output portion of the drive circuit 103 exposed from the second via. In some embodiments, the connection electrode thin film is made of ITO or Mo. The inorganic partition thin film is made of SiO.

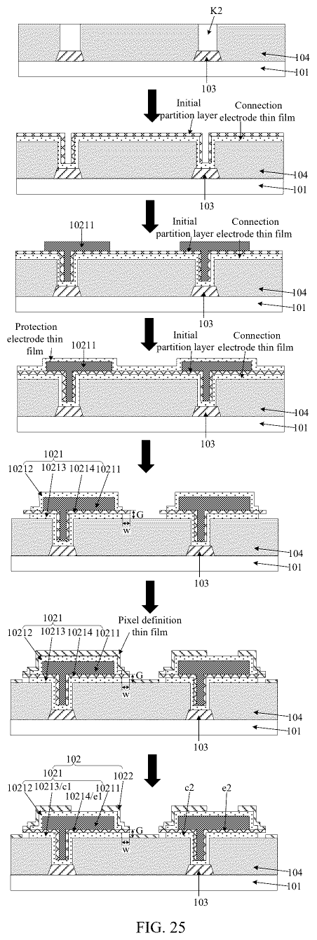

Upon formation of the inorganic partition thin film, the inorganic partition thin film is processed to cause the electrode pattern of the subsequent target electrode layer 10211 to be in contact with the connection electrode thin film. A via exposing the connection electrode thin film is defined in the acquired initial partition layer, and an orthographic projection of the via on the base substrate 101 is within an orthographic projection of the second via K2 in the organic insulative layer 104 on the base substrate 101. That is, referring to FIG. 25, a portion of the connection electrode thin film exposed from the initial partition layer is a portion of the connection electrode thin film within the second via K2.

In S6042, a target electrode thin film is formed on a side, away from the base substrate, of the initial partition layer, and a target electrode layer is acquired by processing the target electrode thin film using a patterning process.

In the embodiments of the present disclosure, the target electrode thin film is made of a three-stack structure (denoted as Ti/Al/Ti) consisting of Ti, Al, and Ti. The etching process in the patterning process is the dry etching process, and Cl2 is used in the dry etching process.

Referring to FIG. 25, the target electrode layer 10211 includes a plurality of electrode patterns. Each electrode pattern is configured to form an anode of a light-emitting unit 102. In addition, each electrode pattern is connected to the drive circuit 103 through the connection electrode thin film within the second via K2 to receive the drive signals provided by the drive circuit 103.

In S6043, a protection electrode thin film is formed on a side, away from the base substrate, of the target electrode layer, and a protection electrode layer, an inorganic partition layer, and a connection electrode layer are acquired by processing the protection electrode thin film, the initial partition layer, and the connection electrode thin film using a patterning process.

In the embodiments of the present disclosure, the protection electrode thin film is made of ITO. Upon formation of the protection electrode thin film, the protection electrode thin film, the initial partition layer, and the connection electrode thin film are processed using a same patterning process.

Referring to FIG. 25, the connection electrode layer 10213 at least includes a first connection pattern c1 and a second connection pattern c2 that are spaced apart by a first spacer h1, and the inorganic partition layer 10214 at least includes a first insulative pattern e1 and a second insulative pattern e2 that are spaced apart by a second spacer h2. The first spacer h1 is greater than the second spacer h2, and the partition structure 10a includes the first spacer h1 and the second spacer h2.

In the case that the protection electrode thin film and the connection electrode thin film are made of ITO, referring to FIG. 25, an orthographic projection of the protection electrode layer 10212 on the base substrate 101 is overlapped with an orthographic projection of the connection electrode layer 10213 on the base substrate 101. In the case that the protection electrode thin film is made of ITO, and the connection electrode thin film is made of Mo, referring to FIG. 25, the protection electrode layer 10212 at least includes a first protection pattern a1 and a second protection pattern a2 that are spaced apart by a fourth spacer h4. The fourth spacer h4 is less than the first spacer h1 and greater than the second spacer h2.

In some embodiments, in the etching process in the patterning process on the protection electrode thin film, the initial partition layer, and the connection electrode thin film, the protection electrode thin film (ITO) is first etched by the wet etching process or the dry etching process, the initial partition layer is then etched by the dry etching process, and the connection electrode thin film (ITO or Mo) is eventually etched by the wet etching process. H2SO4 is used in etching the protection electrode thin film, a mixture of CHF3, Ar, and H2 is used in etching the initial partition layer, and a mixture of HNO3, H3PO4, and CH3COOH is used in etching the connection electrode thin film.

The undercut of the connection electrode layer 10213 relative to the inorganic partition layer 10214 is formed as the etching CD bias of the wet etching process on ITO or Mo is greater than the etching CD bias of the dry etching process on SiO, and thus the partition structure 10a is formed. Furthermore, in the case that the protection electrode thin film is made of ITO, and the connection electrode thin film is made of Mo, the fourth spacer h4 between the protection patterns of the protection electrode layer 10212 is less than the first spacer h1 of the connection patterns of the connection electrode layer 10213 as the etching CD bias of the wet etching process on Mo is greater than the etching CD bias of the dry etching process on ITO.

In S6044, a pixel definition thin film is formed on a side, away from the base substrate, of the protection electrode layer, and a pixel definition layer is acquired by processing the pixel definition thin film using a patterning process.

In the embodiments of the present disclosure, referring to FIG. 25, based on the partition structure 10a, the formed pixel definition thin film is spaced apart by the partition structure 10a. The void in the pixel definition layer 1022 is formed by the same patterning process. Each of the plurality of void regions exposes an electrode pattern, such that the subsequently formed organic functional film layer is in contact with the electrode patterns to achieve display.

In some embodiments, the pixel definition thin film includes a first thin film, a second thin film, and a third thin film that are stacked. The first thin film and the third thin film are made of SiO, and the second thin film is made of SiN. Alternatively, the pixel definition thin film includes a thin film layer of SiO or a thin film layer of SiN. The embodiments of the present disclosure do not limit the detailed structure and material of the pixel definition thin film.

In the case that the pixel definition thin film includes three thin film layer (denoted as SiO/SiN/SiO) consisting of SiO, SiN, and SiO, and initial pixel definition layer 1022a is acquired by processing the pixel definition thin film using the patterning process, SiO/SiN/SiO is etched using a mixture of CHF3, Ar, and H2 in the etching process in the patterning process. That is, SiO and SiN both are etched using the mixture of CHF3, Ar, and H2, and the SiO/SiN/SiO, that is, three layers need to be etched to acquire the void region.

In S6045, an organic functional film layer and a second electrode layer are formed on a side, away from the base substrate, of the pixel definition layer.

In the embodiments of the present disclosure, the organic functional film layer at least includes a charge generation layer, and the charge generation layer needs to be spaced apart as the carrier mobility of the charge generation layer is high. Based on the partition structure 10a, the charge generation layer subsequently formed on a side, away from the base substrate 101, of the pixel definition layer 1022 is spaced apart at the partition structure 10a. Thus, the transverse leakage current due to the high carrier mobility of the film layer is avoided, and the luminous efficiency is ensured.

In general, various film layers on the side, away from the base substrate 101, of the pixel definition layer 1022 in the display panel 10 are increasingly not spaced apart by the partition structure 10a with increment of distances between the various film layers and the pixel definition layer 1022. Thus, the thicknesses of the connection electrode layer 10213 and the inorganic partition layer 10214 are adjusted to adjust the partitioning effect of the partition structure 10a on the various film layers on the side, away from the base substrate 101, of the pixel definition layer 1022 in the display panel.

In some embodiments, as the second electrode layer is farther away from the pixel definition layer 1022 than the charge generation layer, the charge generation layer is prone to being spaced apart by the partition structure 10a than the second electrode layer. Thus, by adjusting the thicknesses of the connection electrode layer 10213 and the inorganic partition layer 10214, the charge generation layer is spaced apart by the partition structure 10a, and the second electrode layer is not spaced apart by the partition structure 10a.

It should be noted that the patterning processes on the film layers prior to the organic insulative layer 104 and the film layers upon the pixel definition layer 1022 are required in each manufacturing method. For description of various manufacturing methods, a number of patterning processes from S6041 to S6044 is used to measure the difficulty of the manufacturing method.

It can be seen from the above description of the processes that the patterning processes from S6041 to S6044 are involved in the following processes. 1. In S6041, the initial partition layer (referred to as mask1) is acquired by processing the inorganic partition thin film. 2. In S6042, the target electrode layer 10211 (referred to as mask2) is acquired by processing the target electrode thin film. 3. In S6043, the protection electrode layer 10212, the inorganic partition layer 10214, and the connection electrode layer 10213 (referred to as mask3) are acquired by processing the protection electrode thin film, the initial partition layer, and the connection electrode thin film. 4. In S6044, the pixel definition layer 1022 (referred to as mask4) is acquired by processing the pixel definition thin film. That is, the manufacturing method according to the embodiments of the present disclosure is a four-mask manufacturing method.

In summary, the embodiments of the present disclosure provide a method for manufacturing a display panel. The display panel acquired by the method includes a base substrate, and a plurality of drive circuits and a plurality of light-emitting units on the base substrate. In addition, the display panel further includes a partition structure. The charge generation layer in the organic functional film layer is spaced apart by the partition structure, and the second electrode layer is not spaced apart by the partition structure, such that the display function of the display panel is ensured, the transverse leakage current is avoided, and the display effect is ensured.

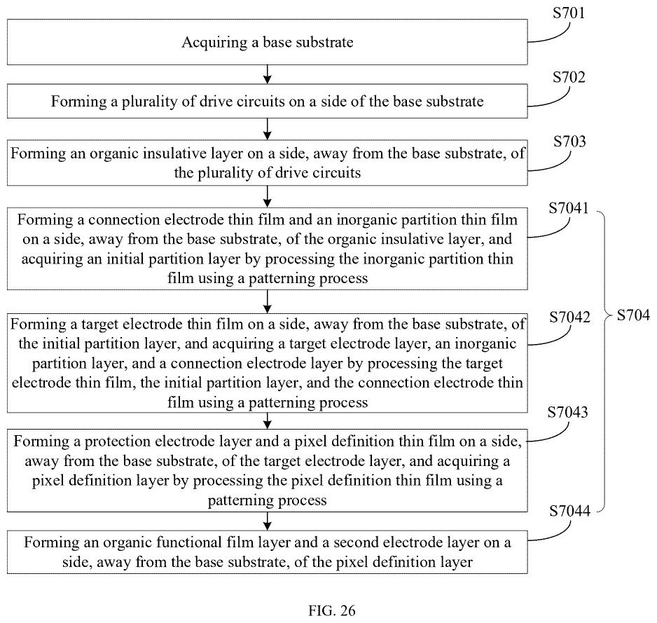

FIG. 26 is a flowchart of a method for manufacturing a display panel according to some embodiments of the present disclosure. Referring to FIG. 26, the method includes the following processes.

In S701, a base substrate is acquired.

In the embodiments of the present disclosure, the base substrate 101 includes a display region 101a and a periphery region 101b surrounding the display region 101a.

In S702, a plurality of drive circuits are formed on a side of the base substrate.

In the embodiments of the present disclosure, various film layers of the thin-film transistors and the storage capacitors in the plurality of drive circuits 103 are formed on the side of the base substrate 101.

In S703, an organic insulative layer is formed on a side, away from the base substrate, of the plurality of drive circuits.

In the embodiments of the present disclosure, the process of forming the organic insulative layer 104 includes: forming an organic insulative thin film on the side, away from the base substrate 101, of the plurality of drive circuits 103, and processing the organic insulative thin film using a patterning process. The patterning process includes photoresist coating, exposing, developing, etching, and photoresist removing.

In some embodiments, the organic insulative layer 104 includes a second via K2. The second via K2 exposes a signal output portion of the drive circuit 103, such that other subsequently formed film layers are connected to the drive circuit 103 through the second via K2 to transmit drive signals.

In S704, a plurality of light-emitting units are formed on a side, away from the base substrate, of the organic insulative layer.

In the embodiments of the present disclosure, the plurality of light-emitting units 102 are disposed in the display region 101a and correspond to the plurality of drive circuits 103, and each of the plurality of drive circuits 103 is connected to a corresponding light-emitting unit 102 to provide a drive signal to the corresponding light-emitting unit 102.

Referring to FIG. 26, the process of forming the plurality of light-emitting units 102 includes the following process.

In S7041, a connection electrode thin film and an inorganic partition thin film are formed on a side, away from the base substrate, of the organic insulative layer, and an initial partition layer is acquired by processing the inorganic partition thin film using a patterning process.

In the embodiments of the present disclosure, at least part of the connection electrode thin film is within the second via K2, and is connected to a signal output portion of the drive circuit 103 exposed from the second via. In some embodiments, the connection electrode thin film is made of ITO or Mo. The inorganic partition thin film is made of SiO.

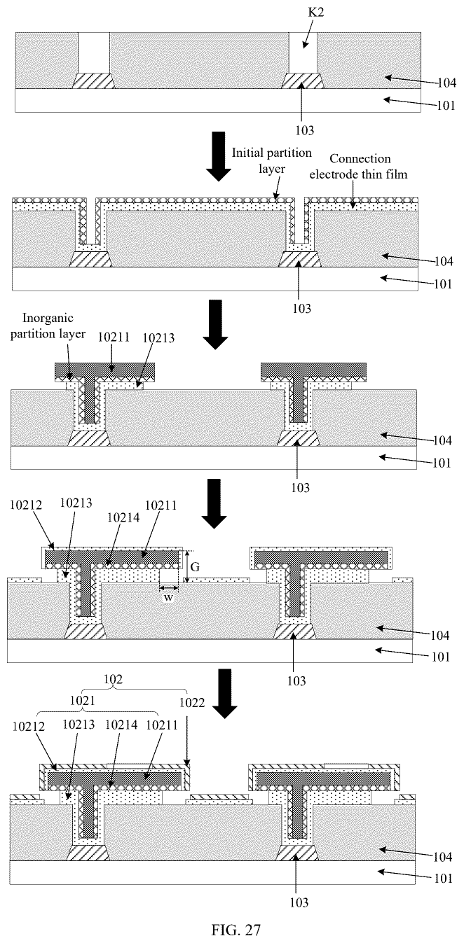

Upon formation of the inorganic partition thin film, the inorganic partition thin film is processed to cause the electrode pattern of the subsequent target electrode layer 10211 to be in contact with the connection electrode thin film. A via exposing the connection electrode thin film is defined in the acquired initial partition layer, and an orthographic projection of the via on the base substrate 101 is within an orthographic projection of the second via K2 in the organic insulative layer 104 on the base substrate 101. That is, referring to FIG. 27, a portion of the connection electrode thin film exposed from the initial partition layer is a portion of the connection electrode thin film within the second via K2.

In S7042, a target electrode thin film is formed on a side, away from the base substrate, of the initial partition layer, and a target electrode layer, an inorganic partition layer, and a connection electrode layer are acquired by processing the target electrode thin film, the initial partition layer, and the connection electrode thin film using a patterning process.

In the embodiments of the present disclosure, the target electrode thin film is made of a three-stack structure (denoted as Ti/Al/Ti) consisting of Ti, Al, and Ti. Upon formation of the target electrode thin film, the target electrode thin film, the initial partition layer, and the connection electrode thin film are processed using a same patterning process.

Referring to FIG. 27, the connection electrode layer 10213 at least includes a first connection pattern c1 and a second connection pattern c2 that are spaced apart by a first spacer h1, and the inorganic partition layer 10214 at least includes a first insulative pattern e1 and a second insulative pattern e2 that are spaced apart by a second spacer h2. The first spacer h1 is greater than the second spacer h2, and the partition structure 10a includes the first spacer h1 and the second spacer h2. In addition, an orthographic projection of the target electrode layer 10211 on the base substrate 101 is overlapped with an orthographic projection of the inorganic partition layer 10214 on the base substrate 101.

In some embodiments, in the etching process in the patterning process on the target electrode thin film, the initial partition layer, and the connection electrode thin film, the target electrode thin film (Ti/Al/Ti) is first etched by the dry etching process, the initial partition layer is then etched by the dry etching process, and the connection electrode thin film (ITO or Mo) is eventually etched by the wet etching process. Cl2 is used in etching the target electrode thin film, a mixture of CHF3, Ar, and H2 is used in etching the initial partition layer, and H2SO4 is used in etching the connection electrode thin film.

The undercut of the connection electrode layer 10213 relative to the inorganic partition layer 10214 is formed as the etching CD bias of the wet etching process on ITO is greater than the etching CD bias of the dry etching process on SiO and Ti/Al/Ti, and thus the partition structure 10a is formed.

In S7043, a protection electrode layer and a pixel definition thin film are formed on a side, away from the base substrate, of the target electrode layer, and a pixel definition layer is acquired by processing the pixel definition thin film using a patterning process.

In the embodiments of the present disclosure, referring to FIG. 27, based on the partition structure 10a, the formed protection electrode layer 10212 is spaced apart by the partition structure 10a. That is, a portion of the protection electrode layer 10212 in the partition structure 10a is incontiguous to a portion of the protection electrode layer 10212 above the target electrode layer 10211.

Furthermore, based on the partition structure 10a, the formed pixel definition thin film is directly spaced apart by the partition structure 10a. That is, a portion of the pixel definition thin film in the partition structure 10a is incontiguous to a portion of the pixel definition thin film above the target electrode.

Thus, the void in the pixel definition layer 1022 is formed by the same patterning process. Each of the plurality of void regions exposes an electrode pattern, such that the subsequently formed organic functional film layer is in contact with the electrode patterns to achieve display.

In some embodiments, the pixel definition thin film includes a first thin film, a second thin film, and a third thin film that are stacked. The first thin film and the third thin film are made of SiO, and the second thin film is made of SiN. Alternatively, the pixel definition thin film includes a thin film layer of SiO or a thin film layer of SiN. The embodiments of the present disclosure do not limit the detailed structure and material of the pixel definition thin film.

In the case that the pixel definition thin film includes three thin film layer (denoted as SiO/SiN/SiO) consisting of SiO, SiN, and SiO, and initial pixel definition layer 1022a is acquired by processing the pixel definition thin film using the patterning process, SiO/SiN/SiO is etched using a mixture of CHF3, Ar, and H2 in the etching process in the patterning process. That is, SiO and SiN both are etched using the mixture of CHF3, Ar, and H2, and the SiO/SiN/SiO, that is, three layers need to be etched to acquire the void region.

In S7044, an organic functional film layer and a second electrode layer are formed on a side, away from the base substrate, of the pixel definition layer.

In the embodiments of the present disclosure, the organic functional film layer at least includes a charge generation layer, and the charge generation layer needs to be spaced apart as the carrier mobility of the charge generation layer is high. Based on the partition structure 10a, the charge generation layer subsequently formed on a side, away from the base substrate 101, of the pixel definition layer 1022 is spaced apart at the partition structure 10a. Thus, the transverse leakage current due to the high carrier mobility of the film layer is avoided, and the luminous efficiency is ensured.

In general, various film layers on the side, away from the base substrate 101, of the pixel definition layer 1022 in the display panel 10 are increasingly not spaced apart by the partition structure 10a with increment of distances between the various film layers and the pixel definition layer 1022. Thus, the thicknesses of the connection electrode layer 10213, the inorganic partition layer 10214, and the target electrode layer 10211 are adjusted to adjust the partitioning effect of the partition structure 10a on the various film layers on the side, away from the base substrate 101, of the pixel definition layer 1022 in the display panel 10.

In some embodiments, as the second electrode layer is farther away from the pixel definition layer 1022 than the charge generation layer, the charge generation layer is prone to being spaced apart by the partition structure 10a than the second electrode layer. Thus, by adjusting the thicknesses of the connection electrode layer 10213, the inorganic partition layer 10214, and the target electrode layer 10211, the charge generation layer is spaced apart by the partition structure 10a, and the second electrode layer is not spaced apart by the partition structure 10a.

It should be noted that the patterning processes on the film layers prior to the organic insulative layer 104 and the film layers upon the pixel definition layer 1022 are required in each manufacturing method. For description of various manufacturing methods, a number of patterning processes from S7041 to S7043 is used to measure the difficulty of the manufacturing method.

It can be seen from the above description of the processes that the patterning processes from S7041 to S7043 are involved in the following processes. 1. In S7041, the initial partition layer (referred to as mask1) is acquired by processing the inorganic partition thin film. 2. In S7042, the target electrode layer 10211, the inorganic partition layer 10214, and the connection electrode layer 10213 (referred to as mask2) are acquired by processing the target electrode thin film, the initial partition layer, and the connection electrode thin film. 3. In S7043, the pixel definition layer 1022 (referred to as mask3) is acquired by processing the pixel definition thin film. That is, the manufacturing method according to the embodiments of the present disclosure is a three-mask manufacturing method.

In summary, the embodiments of the present disclosure provide a method for manufacturing a display panel. The display panel acquired by the method includes a base substrate, and a plurality of drive circuits and a plurality of light-emitting units on the base substrate. In addition, the display panel further includes a partition structure. The charge generation layer in the organic functional film layer is spaced apart by the partition structure, and the second electrode layer is not spaced apart by the partition structure, such that the display function of the display panel is ensured, the transverse leakage current is avoided, and the display effect is ensured.

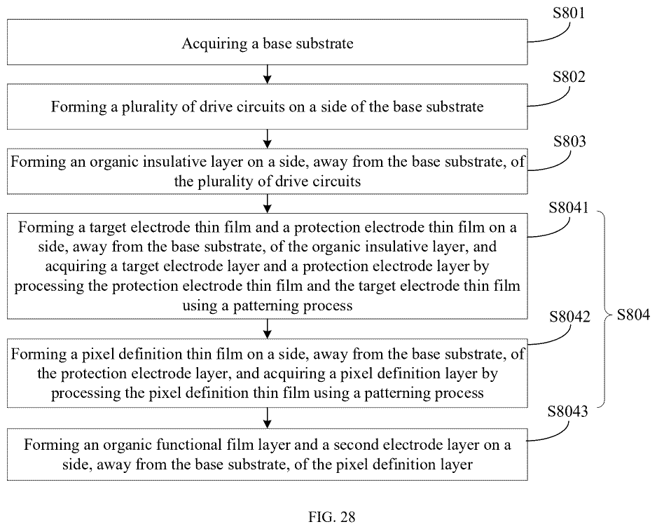

FIG. 28 is a flowchart of a method for manufacturing a display panel according to some embodiments of the present disclosure. Referring to FIG. 28, the method includes the following processes.

In S801, a base substrate is acquired.

In the embodiments of the present disclosure, the base substrate 101 includes a display region 101a and a periphery region 101b surrounding the display region 101a.

In S802, a plurality of drive circuits are formed on a side of the base substrate.

In the embodiments of the present disclosure, various film layers of the thin-film transistors and the storage capacitors in the plurality of drive circuits 103 are formed on the side of the base substrate 101.

In S803, an organic insulative layer is formed on a side, away from the base substrate, of the plurality of drive circuits.

In the embodiments of the present disclosure, the process of forming the organic insulative layer 104 includes: forming an organic insulative thin film on the side, away from the base substrate 101, of the plurality of drive circuits 103, and processing the organic insulative thin film using a patterning process. The patterning process includes photoresist coating, exposing, developing, etching, and photoresist removing.

In some embodiments, the organic insulative layer 104 includes a second via K2. The second via K2 exposes a signal output portion of the drive circuit 103, such that other subsequently formed film layers are connected to the drive circuit 103 through the second via K2 to transmit drive signals.

In S804, a plurality of light-emitting units are formed on a side, away from the base substrate, of the organic insulative layer.

In the embodiments of the present disclosure, the plurality of light-emitting units 102 are disposed in the display region 101a and correspond to the plurality of drive circuits 103, and each of the plurality of drive circuits 103 is connected to a corresponding light-emitting unit 102 to provide a drive signal to the corresponding light-emitting unit 102.

Referring to FIG. 28, the process of forming the plurality of light-emitting units 102 includes the following process.

In S8041, a target electrode thin film and a protection electrode thin film are formed on a side, away from the base substrate, of the organic insulative layer, and a target electrode layer and a protection electrode layer are acquired by processing the protection electrode thin film and the target electrode thin film using a patterning process.

In the embodiments of the present disclosure, at least part of the target electrode thin film is within the second via, and is connected to a signal output portion of the drive circuit 103 exposed from the second via. In some embodiments, the target electrode thin film is made of Mo, Al, or a three-stack structure consisting of Mo/Al/Mo. The protection electrode thin film is made of ITO.

Upon formation of the target electrode thin film and the protection electrode thin film, the target electrode thin film and the protection electrode thin film are processed by a same patterning process.

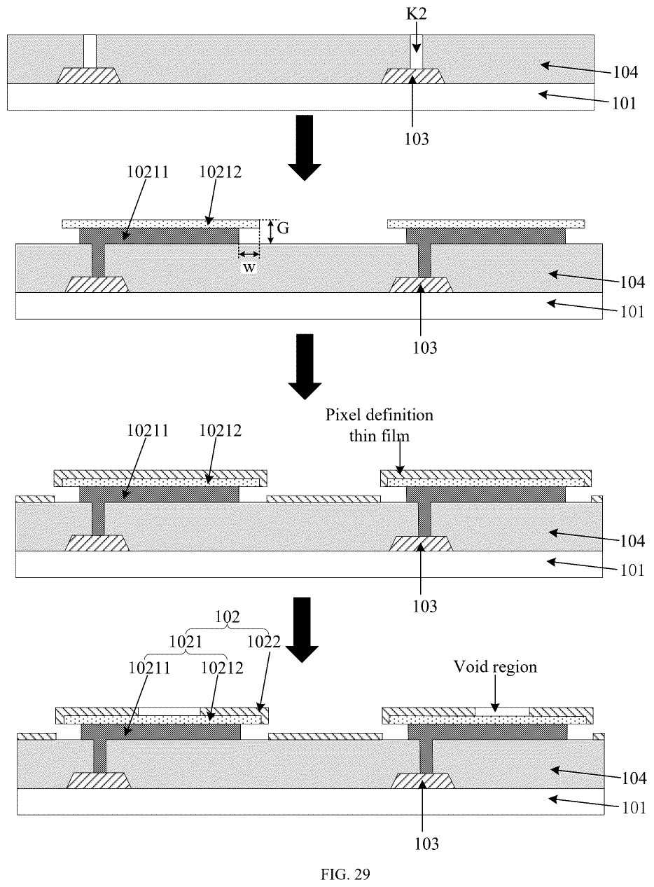

Referring to FIG. 29, the connection electrode layer 10213 at least includes a first connection pattern c1 and a second connection pattern c2 that are spaced apart by a first spacer h1, and the protection electrode layer 10212 at least includes a first protection pattern a1 and a second protection pattern a2 that are spaced apart by a second spacer h2. The first spacer h1 is greater than the second spacer h2, and the partition structure 10a includes the first spacer h1 and the second spacer h2.

In some embodiments, in the etching process in the patterning process on the protection electrode thin film and the target electrode thin film, the protection electrode thin film (ITO) is first etched by the dry etching process or the wet etching process, and the target electrode thin film (Mo or Al or Mo/Al/Mo) is then etched by the wet etching process. H2SO4 is used in etching the protection electrode thin film, and a mixture of HNO3, H3PO4, and CH3COOH is used in etching the target electrode thin film.

The undercut of the target electrode layer 10211 relative to the protection electrode layer 10212 is formed as the etching CD bias of the wet etching process or the dry etching process on ITO is greater than the etching CD bias of the wet etching process on Mo or Al or Ti/Al/Ti, and thus the partition structure 10a is formed.

In the case that the target electrode layer 10211 is made of Mo, the target electrode layer 10211 is not corroded in the subsequent process even if the protection electrode layer 10212 does not cover sidewalls of the target electrode layer 10211.

In the case that the target electrode layer 10211 is made of Al or Mo/Al/Mo, a risk of corrosion is present as the protection electrode layer 10212 does not cover sidewalls of the target electrode layer 10211, but the risk is less because the protection electrode layer 10212 is disposed above the sidewalls of the target electrode layer 10211 to reduce the risk of corrosion of the sidewalls of the target electrode layer 10211 by the plasma in the subsequent film-forming process of the pixel definition layer.

In S8042, a pixel definition thin film is formed on a side, away from the base substrate, of the protection electrode layer, and a pixel definition layer is acquired by processing the pixel definition thin film using a patterning process.

In the embodiments of the present disclosure, referring to FIG. 29, based on the partition structure 10a, the formed pixel definition thin film is spaced apart by the partition structure 10a. That is, a portion of the pixel definition thin film in the partition structure 10a is incontiguous to a portion of the pixel definition thin film above the target electrode.

Thus, the void in the pixel definition layer 1022 is formed by the same patterning process. Each of the plurality of void regions exposes an electrode pattern, such that the subsequently formed organic functional film layer is in contact with the electrode patterns to achieve display.

In some embodiments, the pixel definition thin film includes a first thin film, a second thin film, and a third thin film that are stacked. The first thin film and the third thin film are made of SiO, and the second thin film is made of SiN. Alternatively, the pixel definition thin film includes a thin film layer of SiO or a thin film layer of SiN. The embodiments of the present disclosure do not limit the detailed structure and material of the pixel definition thin film.

In the case that the pixel definition thin film includes three thin film layer (denoted as SiO/SiN/SiO) consisting of SiO, SiN, and SiO, and initial pixel definition layer 1022a is acquired by processing the pixel definition thin film using the patterning process, SiO/SiN/SiO is etched using a mixture of CHF3, Ar, and H2 in the etching process in the patterning process. That is, SiO and SiN both are etched using the mixture of CHF3, Ar, and H2, and the SiO/SiN/SiO, that is, three layers need to be etched to acquire the void region.

In S8043, an organic functional film layer and a second electrode layer are formed on a side, away from the base substrate, of the pixel definition layer.

In the embodiments of the present disclosure, the organic functional film layer at least includes a charge generation layer, and the charge generation layer needs to be spaced apart as the carrier mobility of the charge generation layer is high. Based on the partition structure 10a, the charge generation layer subsequently formed on a side, away from the base substrate 101, of the pixel definition layer 1022 is spaced apart at the partition structure 10a. Thus, the transverse leakage current due to the high carrier mobility of the film layer is avoided, and the luminous efficiency is ensured.

In general, various film layers on the side, away from the base substrate 101, of the pixel definition layer 1022 in the display panel 10 are increasingly not spaced apart by the partition structure 10a with increment of distances between the various film layers and the pixel definition layer 1022. Thus, the thicknesses of the target electrode layer 10211 and the protection electrode layer 10212 are adjusted to adjust the partitioning effect of the partition structure 10a on the various film layers on the side, away from the base substrate 101, of the pixel definition layer 1022 in the display panel 10.

In some embodiments, as the second electrode layer is farther away from the pixel definition layer 1022 than the charge generation layer, the charge generation layer is prone to being spaced apart by the partition structure 10a than the second electrode layer. Thus, by adjusting the thicknesses of the target electrode layer 10211 and the protection electrode layer 10212, the charge generation layer is spaced apart by the partition structure 10a, and the second electrode layer is not spaced apart by the partition structure 10a. It should be noted that the patterning processes on the film layers prior to the organic insulative layer 104 and the film layers upon the pixel definition layer 1022 are required in each manufacturing method. For description of various manufacturing methods, a number of patterning processes from S8041 to S8042 is used to measure the difficulty of the manufacturing method.

It can be seen from the above description of the processes that the patterning processes from S8041 to S8042 are involved in the following processes. 1. In S8041, the target electrode layer 10211 and the protection electrode layer 10212 (referred to as mask1) are acquired by processing the target electrode thin film and the protection electrode thin film. 2. In S8042, the pixel definition layer 1022 (referred to as mask2) is acquired by processing the pixel definition thin film. That is, the manufacturing method according to the embodiments of the present disclosure is a two-mask manufacturing method.

In summary, the embodiments of the present disclosure provide a method for manufacturing a display panel. The display panel acquired by the method includes a base substrate, and a plurality of drive circuits and a plurality of light-emitting units on the base substrate. In addition, the display panel further includes a partition structure. The charge generation layer in the organic functional film layer is spaced apart by the partition structure, and the second electrode layer is not spaced apart by the partition structure, such that the display function of the display panel is ensured, the transverse leakage current is avoided, and the display effect is ensured.

In the embodiments of the present disclosure, the inorganic partition layer 10214 in the above technical solutions may be a single-layer SiO, a single-layer SiN, a two-stack structure SiO/SiN, or a three-stack structure SiO/SiN/SiO.

In addition, the connection electrode layer, the target electrode layer, and the protection electrode layer may be made of other metals, for example, indium zinc oxide (IZO), copper (Cu), and the molybdenum niobium alloy.

In addition, in the technical solutions according to the embodiments of the present disclosure, by appropriately adjusting the etching parameters, the undercut width w and the partition height G of the partition structure, the partition effect of the partition structure on the charge generation layer is adjusted, and other functional layers, for example, the second electrode layer, are not affected.

In the embodiments of the present disclosure, the processes of the above eight manufacturing methods are simple, which reduce a number of the patterning processes relative to the common technical solutions shown in FIG. 2, and thus the manufacturing efficiency is improved and the manufacturing cost is reduced.

In addition, the undercut is formed in different film layers based on different etching conditions in seven manufacturing methods in the eight manufacturing methods except the third method (the method of S301 to S304), and is not formed based on a difference in the etching rate of on a material under the same etching condition, and thus the width of the undercut is controllable.

Furthermore, in the fourth method (the method of S401 to S404), the fifth method (the method of S501 to S504), and the eighth method (the method of S801 to S804)in the eight manufacturing methods, the metal material functions as partition, and thus is not prone to breaking upon being squeezed by the organic functional film layer, such that the partitioning effect is affected.

Furthermore, in the first method (the method of S101 to S104), the second method (the method of S201 to S204), the third method (the method of S301 to S304), the sixth method (the method of S601 to S604), and the seventh method (the method of S701 to S704)in the eight manufacturing methods, the inorganic material functions as partition, and thus the breaking risk of the inorganic material is controlled by controlling the undercut width w being less than 0.1 μm and the partition height G of the partition structure being less than 0.1 μm. In addition, the breaking risk of the inorganic material is further reduced by optimizing the process of forming the film layer upon the pixel demarcation layer.

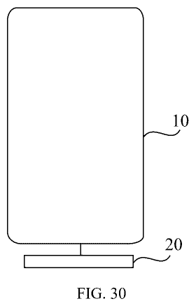

FIG. 30 is a schematic structural diagram of a display device according to some embodiments of the present disclosure. Referring to FIG. 30, the display device includes the power supply assembly 20 and the display panel described in the above embodiments. The power supply assembly 20 is configured to supply power to the display panel 10.

In some embodiments, the display device is an OLED display device or a quantum light-emitting diode (QLED) display device. In some embodiments, the display device is any suitable display device, and includes, but is not limited to a mobile phone, a tablet computer, a television, a monitor, a laptop computer, a digital photo frame, a navigator, and any other product or component with a display function.

As the display substrate achieves basically the same technical effects as the display panel in the above embodiments, and thus the technical effects of the display device are not repeated herein for brevity.

The terms used in the embodiments of the present disclosure are only intended to explain the embodiments of the present disclosure, rather than to limit the present disclosure. Unless otherwise defined, technical or scientific terms used in the embodiments of the present disclosure shall have ordinary meaning understood by persons of ordinary skill in the art to which the disclosure belongs.

The terms used in the embodiments of the present disclosure are only intended to explain the embodiments of the present disclosure, rather than to limit the present disclosure. Unless otherwise defined, technical or scientific terms used in the embodiments of the present disclosure shall have ordinary meaning understood by persons of ordinary skill in the art to which the disclosure belongs. The terms “first,” “second,” “third,” and the like used in the description and claims of the present disclosure are not intended to indicate any order, quantity or importance, but are merely used to distinguish the different components. Similarly, the terms “a,” “an,” and the like are not intended to limit the quantity, and only represent that at least one exists. The terms “comprise” or “include” and the like are used to indicate that the element or object preceding the terms “comprise” or “include” covers the element or object following the terms “comprise” or “include” and its equivalents, and shall not be understood as excluding other elements or objects. The terms “connect” or “contact” and the like are not intended to be limited to physical or mechanical connections, but may include electrical connections, either direct or indirect connection. The terms “on,” “under,” “left,” and “right” are only used to indicate the relative positional relationship. When the absolute position of the described object changes, the relative positional relationship may change accordingly.

Described above are merely optional embodiments of the present disclosure, and are not intended to limit the present disclosure. Any modifications, equivalent replacements, improvements and the like made within the spirit and principles of the present disclosure should be encompassed within the scope of protection of the present disclosure.

1. A display panel, comprising:
a base substrate, wherein the base substrate comprises a display region and a periphery region surrounding the display region;
a plurality of light-emitting units, wherein the plurality of light-emitting units are disposed on a side of the base substrate and disposed in the display region, and each of the plurality of light-emitting units comprises a first electrode layer, a pixel definition layer, an organic functional film layer, and a second electrode layer that are sequentially stacked in a direction away from the base substrate, wherein the first electrode layer comprises a target electrode layer and a protection electrode layer that are stacked in the direction away from the base substrate, an orthographic projection of the protection electrode layer on the base substrate covering an orthographic projection of the target electrode layer on the base substrate, and the organic functional film layer at least comprises a charge generation layer; and
a plurality of drive circuits corresponding to the plurality of light-emitting units, wherein the plurality of drive circuits are disposed between the base substrate and the plurality of light-emitting units, and each of the plurality of drive circuits is connected to a corresponding light-emitting unit to provide a drive signal to the corresponding light-emitting unit;
wherein the display panel further comprises a partition structure between light-emitting regions of any adjacent two of the plurality of light-emitting units; the protection electrode layer at least comprises a first protection pattern and a second protection pattern that are spaced apart by a first spacer; the pixel definition layer at least comprises a first definition pattern and a second definition pattern that are spaced apart by a second spacer, wherein the first spacer is greater than the second spacer, and the partition structure comprises the first spacer and the second spacer; a portion of the charge generation layer in the partition structure is incontiguous to a portion of the charge generation layer in a light-emitting region of each of the plurality of light-emitting units; and a portion of the second electrode layer in the partition structure is contiguous to a portion of the second electrode layer in the light-emitting region of each of the plurality of light-emitting units.

2. The display panel according to claim 1, further comprising: an organic insulative layer and an inorganic protection layer that are disposed between the plurality of light-emitting units and the plurality of drive circuits and stacked in the direction away from the base substrate, wherein the target electrode layer is connected to each of the plurality of drive circuits through a first via in the inorganic protection layer and a second via in the organic insulative layer.

3. The display panel according to claim 1, wherein
the display panel further comprises an organic insulative layer between the plurality of light-emitting units and the plurality of drive circuits; and
the first electrode layer further comprises a connection electrode layer on a side, close to the base substrate, of the target electrode layer, wherein the connection electrode layer is connected to each of the plurality of drive circuits through a second via in the organic insulative layer, the connection electrode layer and the protection electrode layer are formed by a same patterning process, and the connection electrode layer at least comprises a first connection pattern and a second connection pattern that are spaced apart by a third spacer, wherein the partition structure further comprises the third spacer.

4. The display panel according to claim 3, wherein
the connection electrode layer and the protection electrode layer are made of a same material, and the third spacer is equal to the first spacer; or
the connection electrode layer and the protection electrode layer are made of different materials, and the third spacer is not equal to the first spacer.

5-13. (canceled)

14. A method for manufacturing a display panel, comprising:
acquiring a base substrate, wherein the base substrate comprises a display region and a periphery region surrounding the display region;
forming a plurality of drive circuits on a side of the base substrate; and
forming a plurality of light-emitting units on a side, away from the base substrate, of the plurality of drive circuits, wherein the plurality of light-emitting units are disposed in the display region and correspond to the plurality of drive circuits, and each of the plurality of drive circuits is connected to a corresponding light-emitting unit to provide a drive signal to the corresponding light-emitting unit;
wherein forming the plurality of light-emitting units comprises:
forming a connection electrode thin film on the side, away from the base substrate, of the plurality of drive circuits;
forming a target electrode thin film on a side, away from the base substrate, of the connection electrode thin film, and acquiring a target electrode layer by patterning the target electrode thin film;
forming a protection electrode thin film on a side, away from the base substrate, of the target electrode thin film;
acquiring a protection electrode layer by processing the protection electrode thin film using a first etching process, and acquiring a connection electrode layer by processing the connection electrode thin film using a second etching process, wherein the first etching process and the second etching process are a same patterning process, the connection electrode layer at least comprises a first connection pattern and a second connection pattern that are spaced apart by a first spacer, and the protection electrode layer at least comprises a first protection pattern and a second protection pattern that are spaced apart by a second spacer, wherein the first spacer is greater than the second spacer, and the first spacer and the second spacer form a partition structure;
forming a pixel electrode layer on a side, away from the base substrate, of the protection electrode layer, wherein a portion of the pixel electrode layer in the partition structure is incontiguous to a portion of the pixel electrode layer in a light-emitting region of each of the plurality of light-emitting units;
forming an organic functional film layer on a side, away from the base substrate, of the pixel electrode layer, wherein the organic functional film layer at least comprises a charge generation layer, a portion of the charge generation layer in the partition structure being incontiguous to a portion of the charge generation layer in the light-emitting region of each of the plurality of light-emitting units; and
forming a second electrode layer on a side, away from the base substrate, of the organic functional film layer, wherein a portion of the second electrode layer in the partition structure is contiguous to a portion of the second electrode layer in the light-emitting region of each of the plurality of light-emitting units.

15. A display device, comprising: a power supply assembly, and a display panel, wherein
the display panel comprises:
a base substrate, wherein the base substrate comprises a display region and a periphery region surrounding the display region;
a plurality of light-emitting units, wherein the plurality of light-emitting units are disposed on a side of the base substrate and disposed in the display region, and each of the plurality of light-emitting units comprises a first electrode layer, a pixel definition layer, an organic functional film layer, and a second electrode layer that are sequentially stacked in a direction away from the base substrate, wherein the first electrode layer comprises a target electrode layer and a protection electrode layer that are stacked in the direction away from the base substrate, an orthographic projection of the protection electrode layer on the base substrate covering an orthographic projection of the target electrode layer on the base substrate, and the organic functional film layer at least comprises a charge generation layer; and
a plurality of drive circuits corresponding to the plurality of light-emitting units, wherein the plurality of drive circuits are disposed between the base substrate and the plurality of light-emitting units, and each of the plurality of drive circuits is connected to a corresponding light-emitting unit to provide a drive signal to the corresponding light-emitting unit;
wherein the display panel further comprises a partition structure between light-emitting regions of any adjacent two of the plurality of light-emitting units; the protection electrode layer at least comprises a first protection pattern and a second protection pattern that are spaced apart by a first spacer; the pixel definition layer at least comprises a first definition pattern and a second definition pattern that are spaced apart by a second spacer, wherein the first spacer is greater than the second spacer, and the partition structure comprises the first spacer and the second spacer; a portion of the charge generation layer in the partition structure is incontiguous to a portion of the charge generation layer in a light-emitting region of each of the plurality of light-emitting units; and a portion of the second electrode layer in the partition structure is contiguous to a portion of the second electrode layer in the light-emitting region of each of the plurality of light-emitting units; and
the power supply assembly is configured to supply power to the display panel.

16. The display device according to claim 15, wherein the display panel further comprises an organic insulative layer and an inorganic protection layer that are disposed between the plurality of light-emitting units and the plurality of drive circuits and stacked in the direction away from the base substrate, wherein the target electrode layer is connected to each of the plurality of drive circuits through a first via in the inorganic protection layer and a second via in the organic insulative layer.

17. The display device according to claim 15, wherein
the display panel further comprises an organic insulative layer between the plurality of light-emitting units and the plurality of drive circuits; and
the first electrode layer further comprises a connection electrode layer on a side, close to the base substrate, of the target electrode layer, wherein the connection electrode layer is connected to each of the plurality of drive circuits through a second via in the organic insulative layer, the connection electrode layer and the protection electrode layer are formed by a same patterning process, and the connection electrode layer at least comprises a first connection pattern and a second connection pattern that are spaced apart by a third spacer, wherein the partition structure further comprises the third spacer.

18. The display device according to claim 17, wherein
the connection electrode layer and the protection electrode layer are made of a same material, and the third spacer is equal to the first spacer; or
the connection electrode layer and the protection electrode layer are made of different materials, and the third spacer is not equal to the first spacer.

19. The display panel according to claim 4, wherein in a case that the connection electrode layer and the protection electrode layer are made of a same material, the connection electrode layer and the protection electrode layer are made of indium tin oxide (ITO).

20. The display panel according to claim 4, wherein in a case that the connection electrode layer and the protection electrode layer are made of different materials, the connection electrode layer is made of molybdenum (Mo), and the protection electrode layer 10212 is made of indium tin oxide (ITO).

21. The display device according to claim 18, wherein in a case that the connection electrode layer and the protection electrode layer are made of a same material, the connection electrode layer and the protection electrode layer are made of indium tin oxide (ITO).

22. The display device according to claim 18, wherein in a case that the connection electrode layer and the protection electrode layer are made of different materials, the connection electrode layer is made of molybdenum (Mo), and the protection electrode layer 10212 is made of indium tin oxide (ITO).
